(19) United States
(12) Patent Application Publication
(10) Pub. No.: US 2026/0231726 A1
(43) Pub. Date: Aug. 6, 2026

(54) SUBSTRATE PROCESSING APPARATUS

(71) Applicant: Brooks Automation US, LLC, Chelmsford, MA (US)

(72) Inventors: Jairo T. Moura, Marlborough, MA (US); Vincent W. Tsang, Lincoln, MA (US); Robert T. Caveney, Windham, NH (US)

(21) Appl. No.: 19/042,948

(22) Filed: Jan. 31, 2025

(51) Int. Cl. H01L 21/677

(52) U.S. Cl. CPC H10P 72/3202

(57) ABSTRACT

A substrate processing apparatus includes a transport chamber with at least two substrate transport ports arranged side by side; a drive section connected to the transport chamber; and a substrate transport apparatus inside the transport chamber. The substrate transport apparatus including an upper arm link coupled to the drive section and having a shoulder axis disposed at one end of the upper arm link, the upper arm link is mounted inside the transport chamber at the shoulder axis. At least one transfer arm, each having a substrate holder depending therefrom, and each being pivotally mounted to another end of the upper arm link at another axis. The upper arm link is linearly articulated, and each transfer arm is coupled to the drive section so that each transfer arm is coupled independently to and rotated independently by a different independent motor from the at least one motor of the drive section.

### BACKGROUND

### 1. Field

The present disclosure generally relates to substrate processing tools, and more particularly, to substrate transport apparatus.

### 2. Brief Description of Related Developments

Customers continue to build systems with the configuration of having side-by-side process modules or holding stations that require either individual process/service for one process side while also allowing the automation (the term “automation” as used herein means automated equipment configured to effect the acts/functions described herein) to be enabled to load both sides for parallel processing on the side-by-station. In most cases, these cluster tool chambers are configured in a square or pentagon shaped chamber with sufficient size to enable each facet to have a pair of process modules side-by-side. These process modules are usually configured so that they share process gas facilities but can be either operational at the same time or independently shut down for either sequence matching or service. Customers may also desire a reduced footprint (i.e., floor space occupied by the system) of the system. To reduce the footprint of the system, transfer chambers may include transfer apparatus mounted on linear slides where the transfer apparatus linearly traverses a length of the transfer chamber.

Accordingly, the present disclosure addresses a number of those issues.

### BRIEF DESCRIPTION OF THE DRAWINGS

The foregoing aspects and other features of the disclosed embodiment are explained in the following description, taken in connection with the accompanying drawings, wherein:

FIG. 1 is a robot assembly in accordance with the present disclosure;

FIG. 2 is a kinematic chain illustrating a robot assembly in accordance with the present disclosure;

FIG. 3 is a kinematic chain illustrating a robot assembly in accordance with the present disclosure;

FIG. 4 is a drive section for a robot assembly in accordance with the present disclosure;

FIG. 5 is a schematic illustration of an exemplary substrate transfer apparatus in accordance with the present disclosure;

FIG. 6 is a schematic illustration of an exemplary substrate transfer apparatus in accordance with the present disclosure;

FIG. 7 is a schematic illustration of an exemplary substrate transfer apparatus in accordance with the present disclosure;

FIGS. 8A and 8B are schematic illustrations of a portion of an exemplary substrate transfer apparatus in various extension/retraction configurations in accordance with the present disclosure;

FIG. 9A-9C are schematic illustrations of a portion of an exemplary substrate transfer apparatus in accordance with the present disclosure;

FIG. 10 illustrates the substrate transfer apparatus of FIGS. 9A-9C in different configurations in accordance with the present disclosure;

FIG. 11 is a schematic illustration of a portion of a substrate transfer apparatus in accordance with the present disclosure;

FIG. 11A is a schematic illustration of a portion of a substrate transfer apparatus in accordance with the present disclosure;

FIG. 11B is a schematic illustration of a portion of a substrate transfer apparatus in accordance with the present disclosure;

FIG. 12 is a schematic illustration of a portion of a substrate processing apparatus in accordance with the present disclosure;

FIG. 13 is a schematic illustration of end effector extension/retraction to a substrate holding location of the substrate processing apparatus of FIG. 12 in accordance with the present disclosure;

FIG. 14 is a schematic illustration of end effector extension/retraction to a substrate holding location of the substrate processing apparatus of FIG. 12 in accordance with the present disclosure;

FIG. 15 is a schematic illustration of substrate transport apparatus removal from a substrate processing apparatus in accordance with the present disclosure;

FIG. 16 is an exemplary flow diagram of a method in accordance with the present disclosure; and

FIG. 17 is an exemplary flow diagram of a method in accordance with the present disclosure.

### DETAILED DESCRIPTION

The following detailed description is meant to assist the understanding of one skilled in the art, and is not intended in any way to unduly limit claims connected or related to the present disclosure.

The following detailed description references various figures, where like reference numbers refer to like components and features across various figures, whether specific figures are referenced, or not.

The word “each” as used herein refers to a single object (i.e., the object) in the case of a single object or each object in the case of multiple objects. The words “a,” “an,” and “the” as used herein are inclusive of “at least one” and “one or more” so as not to limit the noun being referred to as being in its “singular” form.

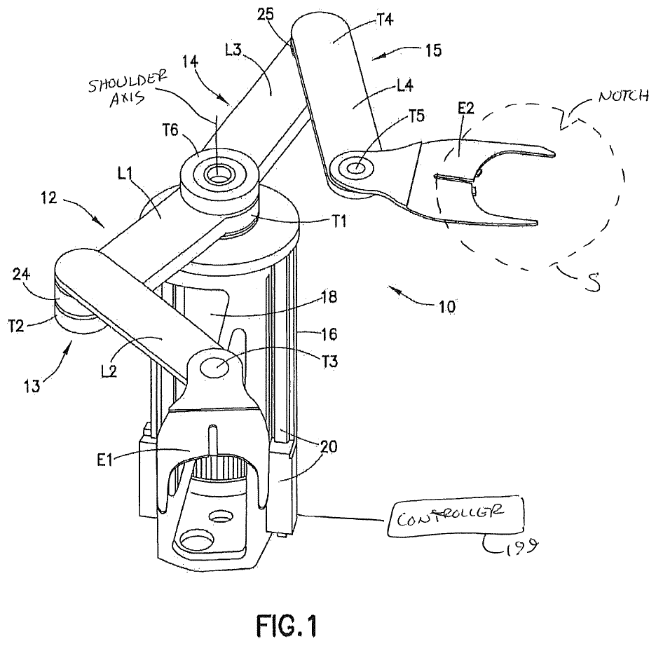

FIG. 1 illustrates an exemplary dual arm SCARA transport apparatus (also referred to herein as a robot assembly) 10 in accordance with the present disclosure. Although the present disclosure will be described with reference to the drawings, it should be understood that the present disclosure can be embodied in many forms. In addition, any suitable size, shape or type of elements or materials could be used.

The present disclosure may provide for substrate transfer automation configured for one or more of the following, individually or in any suitable combination: independent radial and theta degrees of freedom; transfer or swapping of substrates at two side-by-side holding stations in a tandem (e.g., two substrates side-by-side) and placement of substrates, picked from the two side-by-side holding stations, individually to a single substrate holding station at a non-offset radial location; operation in a reduced depth transfer chamber to reduce process system/chamber footprint; extension of greater than about 450 mm beyond a side of a transfer chamber in which the substrate transfer automation operates; wafer swap and wafer orientation (e.g., non-linear wrist); and radial and orientation substrate posture control (e.g., yaw).

The present disclosure may simplify the construction of substrate transfer arms such as by removing bearing and belt components while providing a high reach to containment ratio. The present disclosure may enable easy service access to the substrate transfer arm such as through a side of the transfer chamber in which the substrate transfer arm operates.

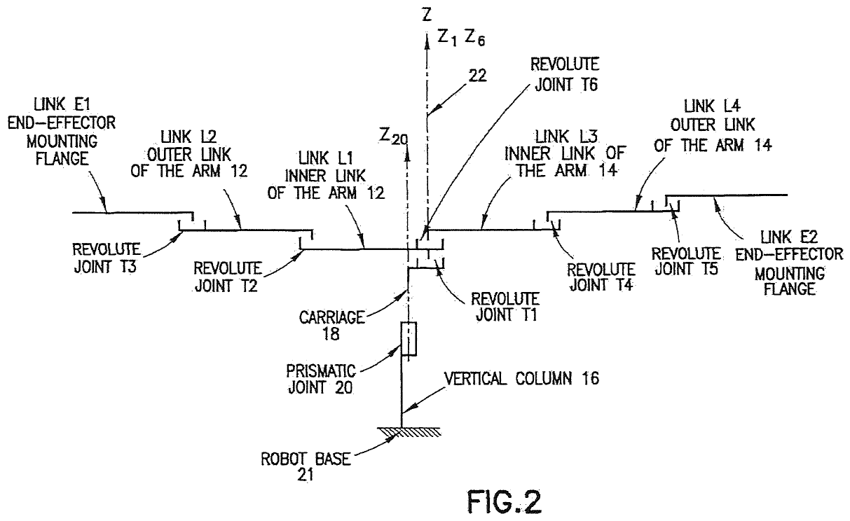

The robot assembly 10 illustrated in FIG. 1 may include two SCARA arms 12, 14 that share a common (i.e., a same) prismatic joint 20/carriage 18 linkage, although the robot assembly may have a single SCARA arm or more than two SCARA arms sharing the common prismatic joint 20/carriage 18 linkage. The common carriage link 18 is located within the envelope of a column 16. Each arm includes a limb 13, 15 that is movable in a horizontal plane and mounted atop the common carriage link 18. Referring to the kinematic chain illustrated schematically in FIG. 2, four joint/link pairs are evident for each arm, and the arms may be coupled to the prismatic joint 20/carriage 18 for movement in the Z direction. Referring to arm 12, these pairs are the prismatic joint 20/carriage 18, revolute joint T1/inner link (also referred to as an upper arm link) L1, revolute joint T2/outer link (also referred to as a forearm link) L2, and revolute joint T3/link (also referred to as an end effector) E1 (although more than one end effector may be provided). Referring to arm 14, these pairs are the prismatic joint 20/carriage 18, revolute joint T6/inner link (also referred to as an upper arm link) L3, revolute joint T4/outer link LA (also referred to as a forearm link), and revolute joint T5/link (also referred to as an end effector) E2 (although more than one end effector may be provided). The limbs 13, 15 are mounted for revolution about the axis of revolute joints T1 and T6 respectively. In this arrangement, a Z-axis 22 positioned along the axis of the joints T1 and T6 can be located and described as a common (i.e., a same) axis 22 of the carriage 18. The limbs 13, 15 of both arms 12, 14 are able to extend and retract in a radial direction independently of each other.

Each distal most link E1, E2 may support a tool. In the semiconductor industry, these links E1, E2 are referred to as end effector mounting flanges, and are connected to the outer links L2, L4 of the manipulator via the wrist rotary joints T3 and T5. The tools supported by the end effector mounting flanges are often called end effectors. The end effector mounting flanges may be identical or different, depending on the application.

Motion of a particular joint causes the links attached to that joint to move. Upon actuation, each limb 13, 15 is able to move in a distal or a proximal direction to provide straight-line radial translation of the end effector, maintaining a projection of the axis of the end effector aligned to intersect the common axis 22 of the carriage 18, about which the links L1 and L3, connected via the rotary joints T1 and T2 rotate. For purposes of description in the present disclosure, the term “distal” is a relative term that refers to a direction generally away from the common axis 22. The term “proximal” is a relative term that refers to a direction generally toward the common axis 22.

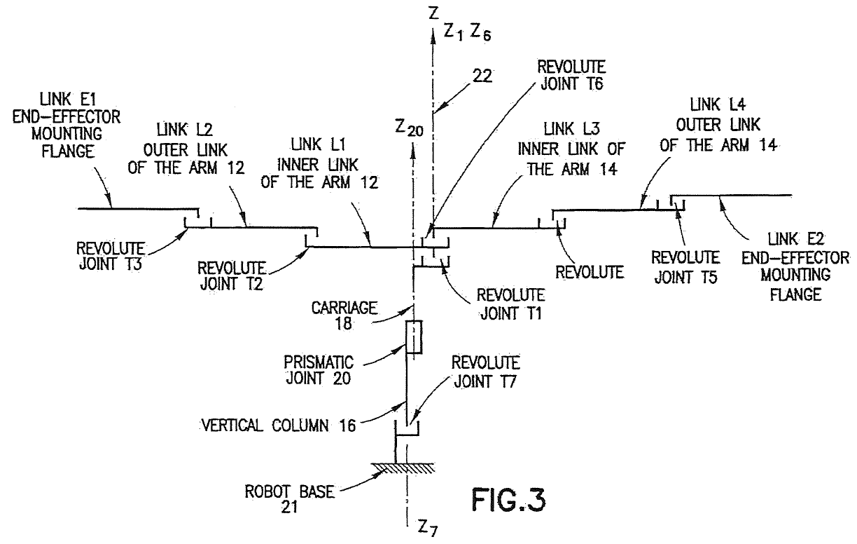

The carriage 18 is connected via the prismatic joint 20 to a vertical column 16 for vertical linear motion along the axis Z20 of the vertical column 16. See FIG. 2. The axis Z20 is parallel to the common axis 22 of the carriage 18, about which the links L1 and L3 rotate. The two limbs 13, 15 are supported by the carriage 18 on the column 16. The vertical column 16 may be mounted for rotation on a base 21 via a revolute joint T7, as indicated schematically in FIG. 3. The base 21 may be referred to as link L0. The column may allow for vertical movement of the arm assemblies and the carriage 18 as a unit in the Z direction and, if the revolute joint T7 is present, the column 16 may rotate about the axis of the joint T7 with respect to the robot's base 21 containing the joint's actuator.

As noted above, each inner link L1, L3 is attached to the carriage 18 via a proximal, or shoulder, rotary joint T1, T6. The shoulder joints T1, T6 of the two arms 12, 14 are co-linear on the common axis 22 of the carriage 18 and vertically offset, one above the other. The end effector mounting flanges E1, E2 move in horizontal planes that are parallel to each other, one horizontal plane may be substantially coincident or offset vertically from the other horizontal plane. The elbow joint of at least one arm, joint T2 of arm 12, may include a spacer 24 to space the outer link L2 from the inner link L1 by an amount sufficient to offset the two end effector mounting flanges E1, E2 vertically. In FIG. 1, the limbs are illustrated as being the same length, the joint T4 may include a spacer 25 to space the outer link LA from the inner link L3 by an amount sufficient to offset the two end effector mounting flanges E1 and E2 vertically. The end effectors may not interfere with each other when the two arm assemblies are configured for moving independently with unrestricted rotation about the Z-axis.

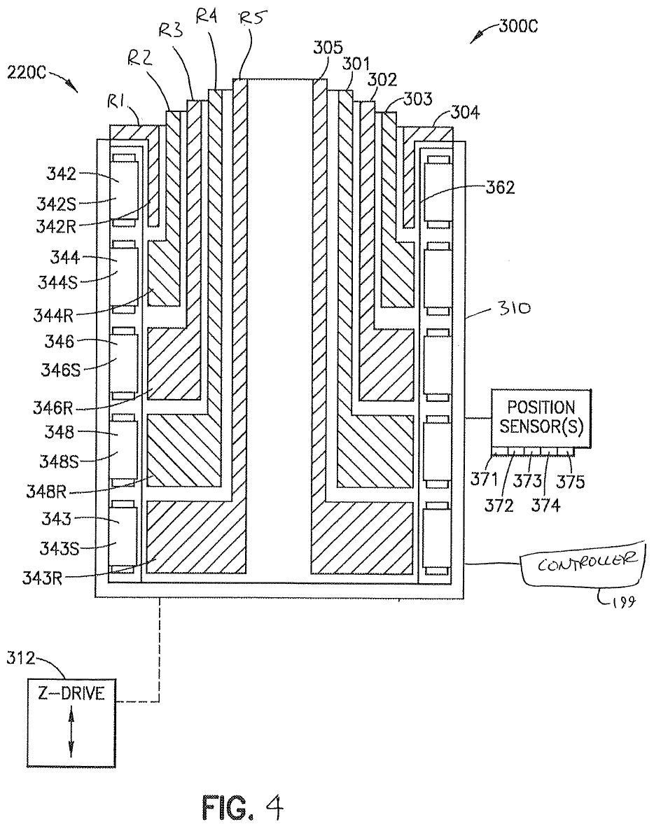

The two SCARA arms 12, 14 are driven by, and the robot assembly 10 includes, what may be referred to as a five-axis drive system, where the two limbs 13, 15 of the robot assembly 10 are independently operable. The term “five-axis” refers to the system of revolute joint/link pairs that allow the motion of the limbs 13, 15 of the arms 12, 14 in a plane described by polar R-0 coordinates. For descriptive purposes only, the mechanism of the vertical displacement of the arm is not included in the term “five-axis.”Referring to FIG. 4, a five-axis drive section 220C, is illustrated for exemplary purposes. The drive section 220C includes a housing 310 for at least partially housing a quintuple-coaxial drive shaft assembly 300C having five drive shafts 301-305 and five motors 342, 344, 346, 348, 343 (e.g. a five-degree of freedom motor or five-axis motor/drive section). The drive section 220C may include a Z-axis drive 312 configured to, e.g., raise and lower the arm (such as those described herein) of the robot assembly 10 for picking and placing substrates S; however, the substrate holding stations coupled to the transfer chamber in which the robot assembly 10 is at least partially located may include Z-axis drive(s) for lifting and lowering the substrates from and to the robot assembly 10 in lieu of or in addition to the Z-axis drive 312 of the drive section 220C.

The first motor 342 of the drive section 220C includes a stator 342S and a rotor 342R connected to the outer shaft 304 (e.g., the R1 axis of rotation), where the outer shaft 304 may drive rotation of the upper arm links L1, L3. The second motor 344 includes a stator 344S and a rotor 344R connected to shaft 303 (e.g., the R2 axis of rotation), where the shaft 303 drive rotation of the forearm link L2. The third motor 346 includes a stator 346S and a rotor 346R connected to shaft 302 (e.g., the R3 axis of rotation), where the shaft 302 drives rotation of the forearm link L4. The fourth motor 348 includes a stator 348S and a rotor 348R connected to shaft 301 (e.g., the R4 axis of rotation), where the shaft 301 drives rotation of the end effector link E1. The fifth motor 343 includes a stator 343S and a rotor 343R connected to shaft 305 (e.g., the R5 axis of rotation), where the shaft 305 drives rotation of the end effector link E2. Any suitable transmissions may be employed to couple the respective arm links to the respective drive shafts. The five stators 342S, 344S, 346S, 348S, 343S are stationarily attached to the housing 310 at different vertical heights or locations within the housing. Each stator 342S, 344S, 346S, 348S, 343S generally comprises an electromagnetic coil. Each of the rotors 342R, 344R, 346R, 348R, 343R generally comprises permanent magnets (e.g., a permanent magnet rotor); however, the motors 342, 344, 346, 348, 343 may be configured as induction motors where the rotor is a magnetic induction rotor that does not have permanent magnets, or the motors 342, 344, 346, 348, 343 may be variable or switched reluctance motors such as those described in U.S. Pat. Nos. 10,348,172 and 9,948,155 and United States patent application number Ser. No. 14/540,058 titled “Position Feedback for Sealed Environments” filed on Nov. 13, 2014, the disclosures of which are incorporated herein by reference in their entireties, or the motors 342, 344, 346, 348, 343 may be harmonic drives such as those described in U.S. Pat. No. 9,656,386 the disclosure of which is incorporated herein by reference in its entirety. Where the robot assembly 10 is used in a sealed environment, such as for non-limiting exemplary purposes only, a vacuum environment, sleeves 362 may be located between the rotors 342R, 344R, 346R, 348R, 343R and the stators 342S, 344S, 346S, 348S, 343S so that the coaxial drive shaft assembly 300C is located in the sealed environment and the stators are located outside the sealed environment. The sleeves 362 need not be provided if the robot assembly 10 is only intended for use in an atmospheric environment, such as within an atmospheric section of any suitable substrate processing apparatus.

The shaft 305 extends from the fifth stator 343S and includes rotor 343R, which is substantially aligned with the stator 343S. The shaft 302 extends from the third stator 346S and includes rotor 346R, which is substantially aligned with the stator 346S. The shaft 301 extends from the fourth stator 348S and includes rotor 348R, which is substantially aligned with the stator 348S. The shaft 303 extends from the second stator 344S and includes the rotor 344R, which is substantially aligned with the stator 344S. The shaft 304 extends from the top or first stator 342S and includes rotor 342R, which is substantially aligned with the stator 342S. Various bearings are provided about the shafts 301-305 and the housing 310 to allow each shaft 301-305 to be independently rotatable relative to each other and the housing 310. It is noted that each shaft may be provided with a position sensor 371-375. The position sensors 371-375 may be used to provide a signal to any suitable controller, such as controller 170, regarding the rotational position of a respective shaft 301-305 relative to each other and/or relative to the housing 310. The sensors 371-375 may be any suitable sensors, such as for non-limiting exemplary purposes, optical or induction sensors. The drive section 220C is configured to extend and retract at least one of the arms 12, 14 along a non-radial linear path or a radial linear path.

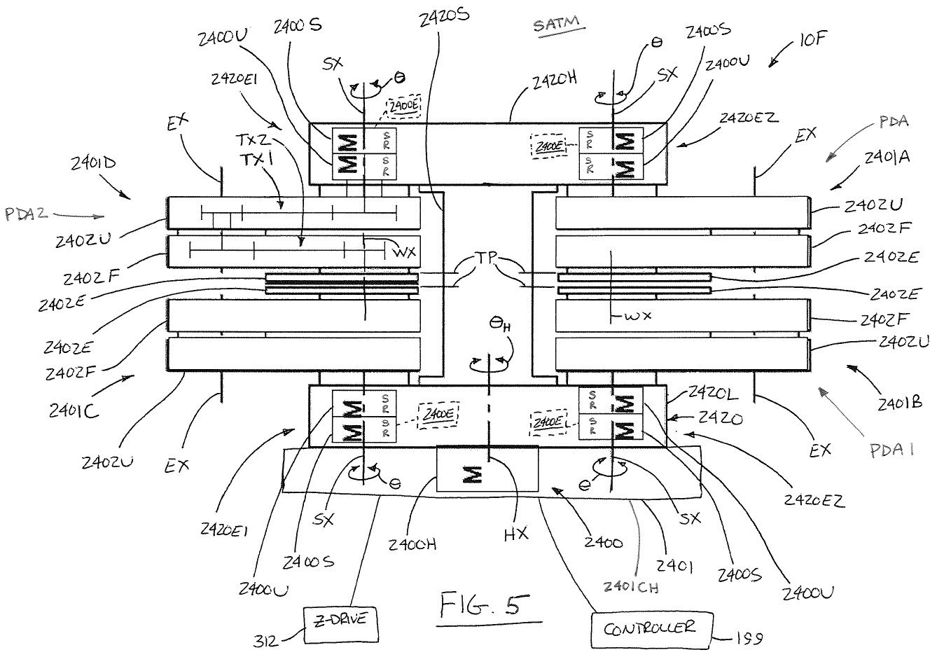

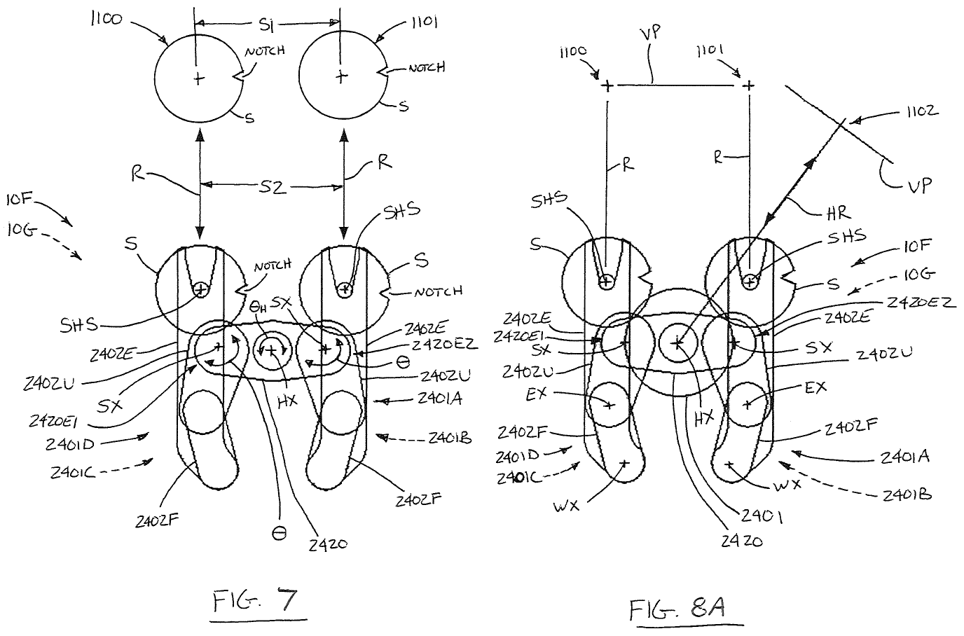

Referring to FIGS. 5-8B, a robot assembly (also referred to as a substrate transport apparatus) 10F, 10G is illustrated and includes four independent SCARA arms 2401A-2401D coupled to a hub or base link 2420 and a distributed drive section 2400 for driving rotation of the hub 2420 and rotation and extension of the arms 2401A-2401D. As described herein, each of the arms 2401A-2401D may have independent radial R and rotational 0 degrees of freedom (see also FIG. 7).

The robot assembly 10F, 10G includes a frame 2401 and the base link or hub 2420 is pivotally joined to the frame 2401 so as to rotate relative to the frame 2401 about a base pivot joint axis of rotation HX fixed to the frame 2401. A pair of dual arms PDA having first dual arms PDA1 and second dual arms PDA2. The first dual arms PDA1 are juxtaposed with respect to the second dual arms PDA2. The first dual arms PDA have a first top arm 2401A with a first top end effector 2402E, and a first bottom arm 2401B with a first bottom end effector 2402E. The second dual arms PDA2 have a second top arm 2401D with a second top end effector 2402E, and a second bottom arm 2401C with a second bottom end effector 2402E.

The first top arm 2401A has a corresponding top terminal joint SX, and the first bottom arm 2401B has a corresponding bottom terminal joint SX. Each of the first top arm 2401A and the first bottom arm 2401B respectively rotates and extends from the corresponding top terminal joint SX and bottom terminal joint SX. The top terminal and bottom terminal joint SX being coaxial and respectively joining each first top and bottom arm 2401A, 2401B to the base link 2420 via the corresponding top terminal joint and bottom terminal joint SX. The first top arm 2401A has at least one first top arm link 2402U, 2402F and the first top end effector 2402E is dependent from a top distal link (e.g., forearm link 2402F) of the first top arm 2401A. The first bottom arm 2401B has at least one bottom arm link 2402U, 2402F and the first bottom end effector 2402E is dependent from a bottom distal link (e.g., forearm link 2402F) of the first bottom arm 2401B. Each arm link of the first top arm 2401A is separate and distinct from each arm link of the first bottom arm 2401B, and the first top and bottom end effector 2402E extend overlapping each other at least in part.

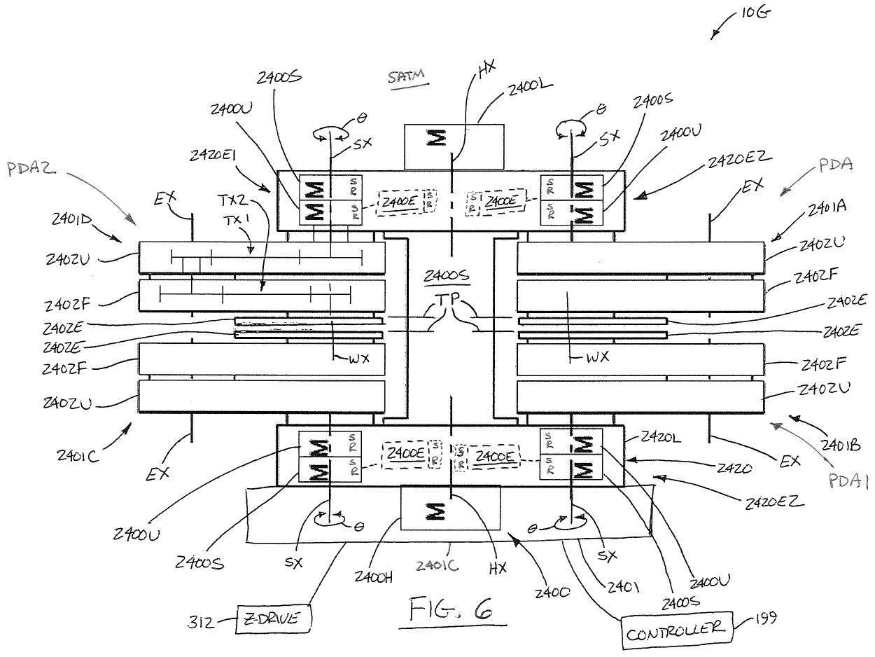

The drive section 2400 has at least one motor 2400S, 2400U, 2400E (see FIGS. 5 and 6) connected to each respective arm 2401A,-2401D, of the pair of dual arms PDA. The at least one motor 2400S, 2400U, 2400E is arranged to extend each respective arm 2401A-2401D with at least one degree of freedom, independent of each other respective arm 2401A-2401D of the pair of dual arms PDA. The drive section 2400 has at least another motor 2400H, 2400L connected to the base link 2420 so as to rotate the base link 2420 about the base pivot joint axis of rotation HX so that each corresponding end effector 2402E of the respective arm 2401A-2401D is extended and rotated along a substantially level substrate transport plane TP.

Each respective top arm 2401A, 2401D of the first and second dual arms PDA1, PDA2, or each respective bottom arm 2401B, 201C of the first and second dual arms PDA1, PDA2, are arranged to: effect substantially simultaneous dual extension and retraction with juxtaposed moves of the respective first top arm 2401A and second top arm 2401D, or the respective first bottom arm 2401B and second bottom arm 2401C; and effect extension and retraction of at least the first top arm 2401A or the second top arm 2401D along a radial path R extending from the base pivot joint axis of rotation HX.

The frame 2401 may be a chamber 2401CH (such as, e.g., any suitable transfer chamber or other chamber as described herein, only a portion of which is illustrated in FIGS. 5 and 6) arranged to hold a sealed atmosphere SATM therein. The at least one motor 2400U, 2400S, 2400E may be located within the sealed atmosphere SATM of the chamber, housed in a sealed housing (such as formed by one or more of: the base link or hub 2420, arm link(s) 2402U of one or more of the arms 2401A-2401D, and arm link(s) 2402F of one or more of the arms 2401A-2401D) sealed from the sealed atmosphere, where the sealed housing seals a rotor R and/or stator S of the at least one motor 2400S, 2400U, 2400E from the sealed atmosphere SATM.

The at least one other motor 2400H, 2400L of the drive section 2400 may include more than one other motor 2400H, 2400L, each coupled to the base link 2420 and arranged so that the base link rotation about the base pivot joint axis of rotation HX has more than one degree of freedom. As described herein, the base link 2420 may be configured so that the more than one degree of freedom are each disposed to effect rotation and extension, along the radial path R, of the first top arm 2401A and the second top arm 2401D decoupled from rotation and extension, along the radial path R, of the first bottom arm 2401B and second bottom arm 2401C.

Referring again to FIG. 5, the robot assembly 10F includes the base or frame 2401 to which a hub 2420 is rotatably coupled for rotation (i.e., rotational degree of freedom OH) about a hub axis of rotation HX. In FIG. 5 the hub 2420 includes a proximate hub portion 2420L and a distal hub portion 2420H that are coupled to each other by a stanchion 2420S such that the proximate hub portion 2420L is proximate the base 2401 and the distal hub portion 2420H is distal to the base 2401 and are rotated about the hub axis HX as a single unit. The drive section 2400 includes motor 2400H that is coupled to the hug 2420 for driving rotation of the hub 2420 about the hub axis of rotation HX. The motor 2400H may be similar to any of the motors described herein.

The stanchion 2420S is sized so that the distal and proximate hub portions 2420H, 2420L are spaced from one another by any suitable distance where the arms 2401A-2401D are disposed between the distal and proximate hub portions 2420H, 2420L, although any other suitable arrangement of the arms 2401A-2401D relative to the stanchion and hub portions 2420H, 2420L may be employed.

Each of the distal and proximate hub portions 2420H, 2420L extend on opposite sides of the hub axis of rotation HX so that each of the distal and proximate hub portions 2420H, 2420L have a first and second ends 2420E1, 2420E2. The arm 2401A is coupled to the distal hub portion 2420H adjacent end 2420E2 and the arm 2401B is coupled to the proximate hub portion 2420L adjacent end 2420E2 so that the arms 2401A, 2401B are stacked one above the other in an opposing relationship (i.e., the end effector 2402E of arm 2401A is adjacent the end effector 2402E of arm 2401B) so that the transfer planes TP of the arms 2401A, 2401B are adjacent each other to minimize a Z travel of the arms 2401A, 2401B when picking/placing substrates S to the same or different substrate holding stations. The arm 2401D is coupled to the distal hub portion 2420H adjacent end 2420E1 and the arm 2401C is coupled to the proximate hub portion 2420L adjacent end 2420E1 so that the arms 2401D, 2401C are stacked one above the other in an opposing relationship (i.e., the end effector 2402E of arm 2401D is adjacent the end effector 2402E of arm 2401C) so that the transfer planes TP of the arms 2401A, 2401B are adjacent each other to minimize a Z travel of the arms 2401A, 2401B when picking/placing substrates S to the same or different substrate holding stations. Coupling the arms 2401A-2401D to the hub 2420 provides for rotation of the arms 2401A-2401D with the hub 2420 about the hub axis HS as a single unit.

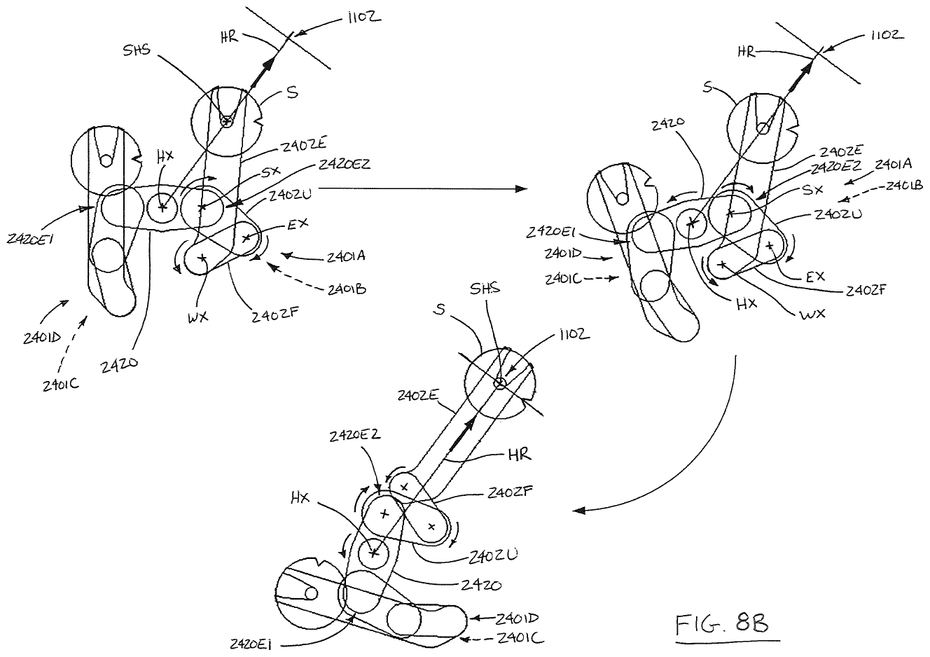

The arms 2401A-2401D are mounted or otherwise coupled to the hub 2420 to effect the independent radial R and rotational 0 degrees of freedom movement. For example, referring to arm 2401D (the other arms 2401A-2401C have the same arrangement) the arm 2401D includes an upper arm link 2402U (referred to as an upper arm) that is coupled to the hub 2420 about a respective shoulder axis SX. A forearm link 2402F (referred to as a forearm) of the arm 2401D is rotatably coupled to the upper arm 2402U about a respective elbow axis EX. An end effector 2402E (there may be more than one end effector coupled to each of the arm 2401A-2401D) is rotatably coupled to the forearm 2402F about a respective wrist axis WX. The drive section includes motors 2400U, 2400S that are disposed in the hub 2420 at the respective shoulder axis SX. The motor 2400U is coupled to the upper arm 2402U for rotating the upper arm 2402 U about the respective shoulder axis SX. The motor 2400S is coupled to the forearm 2402F through any suitable transmission TX1 (such as a band and pulley transmission) for rotation the forearm about the respective elbow axis EX. The rotation of the end effector 2402E about wrist axis WX may be slaved to the upper arm 2402U through any suitable transmission TX2 (such as a band and pulley transmission) so that as the arm 2401D is extended and retracted the end effector 2401E is aligned with and travels along a radial path R (see FIG. 7) that passes through the respective shoulder axis SX. Rotation of both motors 2400U, 2400S at the same rate in the same direction causes rotation of the arm 2401D as a single unit about the respective shoulder axis, where rotation of the motors 2400U, 2400S at different rates in the same or different directions causes extension and retraction of the arm 2401D along the radial path R (or radial path HR-see FIG. 8A). While a slaved end effector 2402E is described for each of the arms 2401A-2401D, the end effector 2402E of each arm may be provided with independent rotation where a third motor 2400E is located at the respective shoulder axis SX of each arm 2401A-2401D for driving rotation of the respective end effector 2402E through any suitable transmission (such as the band and pulley transmission). Although the motors 2400A, 2400U, and where included motor 2400E, are described as being located at the shoulder axis, the motor 2400U may be disposed at the shoulder axis, the motor 2400S may be disposed at the elbow axis, and the motor 2400E (where provided) may be disposed at the wrist axis WX so as to be distributed throughout a respective arm 2401A-2401D.

Referring to FIG. 6, a robot assembly 10G is illustrated. The robot assembly 10G is the same as the robot assembly 10F but for the hub portion 2420H being rotatably coupled to the stanchion 2420S and driven in rotation about the hub axis of rotation HX, independent of hub portion 2420L, by respective motor 2400L.

The orientation (i.e., of the notch location of the substrate) and position of a substrate S may be controlled, when handing off a substrate S between two robot assemblies (such as robot assemblies 10, 10F, and 10G) in the manner described in International application number PCT/US 2024/045027 having an international filing date of Sep. 3, 2024 (the disclosure of which is incorporated herein by reference in its entirety) so that the notch of the substrate S (which indicates a predetermined alignment for processes performed on the substrate S) is to be oriented with substantially the same orientation from process to process. For example, at least three axes of control may be provided for each substrate S held and transported by the dual arm robot assembly 10. The three axes of control per substrate S may provide for maintaining substrate orientation (during process tool operation) where multiple robots in the same system hand off the substrate from one robot to another (e.g., such as between an atmospheric robot and a vacuum robot, between two atmospheric robots, between two vacuum robots, etc.) with varying handoff angles.

With respect to the FIGS. 5 and 6 and the robot assemblies 10F and 10G, handoff of substrates S may be effected without relative substrate S rotation, with slaved end effectors 2402E, where the spacing S1 between side-by-side handoff stations 1100, 1101 (see at least FIGS. 7 and 8A) is substantially the same as the spacing S2 between the radial extension/retraction axes R (i.e., the spacing between the shoulder axes SX on opposite ends 2420E1, 2420E of the hub 2420), and the hub rotation axis HX is disposed substantially midway between the handoff stations 1100, 1101. Where independent rotation of the end effectors 2402E is provided, the spacing S1 between handoff stations 1100, 1101 may be the same or different than the spacing between the radial extension/retraction axes R and the hub rotation axis X may be disposed at any spatial location relative to the handoff stations 1100, 1101 so long as the handoff stations 1100, 1101 are within reach of the arms 2401A-2401D. With independent rotation of the end effectors 2402E of the robot assemblies 10F, 10G, at least the motors 2400U, 2400S, 2400E are operated such that the arms 2401A-2401D may be extended so that the end effectors 2402E follow respective non-radial paths of extension to the handoff stations 1100, 1101 in a manner similar to that described in International application number PCT/US2024/045027 having an international filing date of Sep. 3, 2024.

Still referring to FIGS. 5, 6, and also to FIGS. 7 and 8A-8B, the robot assemblies 10F, 10G may be configured for placing substrates at side by side substrate handoff stations 1100, 1101 and radially disposed (relative to the hub axis of rotation HX) to the substrate handoff stations 1102, where the end effectors 2402E place substrates S at each of the substrate handoff stations 1100, 1101, 1102 with the end effector orthogonal to the respective vertical planes VP of the holding stations 1100, 1101, 1102. Handoff to substrate handoff stations 1100, 1101 with the robot assemblies 10F, 10G is described above. Handoff to what may be referred to as a radial handoff station 1102 (e.g., handoff to another robot assembly, process module, load lock, etc.) may be effected by a coordinated control of the drive section 2400 motors so that a substrate holding station center SHS of the end effectors 2402E follows the path of radial extension HR to the substrate holding station 1102, and so that the end effectors 2402E are orthogonal to the vertical plane VP of the substrate holding station 1102 to effect substrate S handoff such that no relative substrate S rotation occurs at the substrate holding station 1102 (such as where handoff is to another robot assembly).

To effect extension to substrate holding station 1102, using arm 2401A as an example (extension of the other arms 2401B-2401D is effected in the same/similar manner), the controller 199 operates one or more of the motors 2400U, 2400S so that the arm 2401A is extended to place the substrate holding station center SHS of the end effector 2402E on the path of radial extension HR (see the top left of FIG. 8B). With the substrate holding station center SHS on the path of radial extension HR, the controller 199 operates the motor 2400H to rotate the hub 2401 about the hub axis of rotation HX in direction OH to move the shoulder axis SX of the arm 2401A towards the path of radial extension HX. With movement of the hub 2401 in direction OH, the controller 199 operates one or more of the motors 2400U, 2400S (the motors 2400H, 2400U, 2400S being operated by the controller 199 in a coordinated manner) to extend the arm 2401A where the combined movement effected by the motor 2400H and the one or more of the motors 2400U, 2400S maintains travel of the substrate holding station center SHS along the path of radial extension HR (see the top right of FIG. 8B). Operation of one or more of the motors 2400H, 2400U, 2400S continues so that the end effector aligns with the path of radial extension HR (so as to be orthogonal to the vertical plane VP of the substrate handoff station 1102) and so that the substrate holding station center SHS is positioned to pick or place a substrate S to the substrate holding station 1102. Retraction of the arm 2401A (and the other arms 2401B-2401D) is effected in a substantially reverse manner to that described with the extension of the arm 2401A. With extension/retraction of the arms 2401A-2401D the controller 199 may operate only one of the motors 2400H, 2400U, 2400S and/or a combination of two or more of the motors 2400H, 2400U, 2400S in a predetermined sequence to maintain the substrate holding station center SHS along the path of radial extension HR. For example, to extend an arm 2401A-2401D the may be time periods of the extension/retraction in which only motors 2400U and 2400S operate simultaneously, other time periods where only motor 2400H operates, and still other time periods where motors 2400H, 2401U, 2400S operate simultaneously to place the substrate holding station center SHS on the path of radial extension HR and/or to maintain the substrate holding station center SHS on the path of radial extension HR.

As illustrated in FIGS. 8A and 8B while the arm 2401A (and/or arm 2401B) is extended, the arms 2401C, 2401D disposed on the opposite end 2420E1 of the hub 2420 remain substantially in a retracted configuration. Likewise, where arm 2401D (and/or arm 2401C) is extended the arms 2401A, 2401B disposed on the opposite end 2420E2 remain substantially retracted.

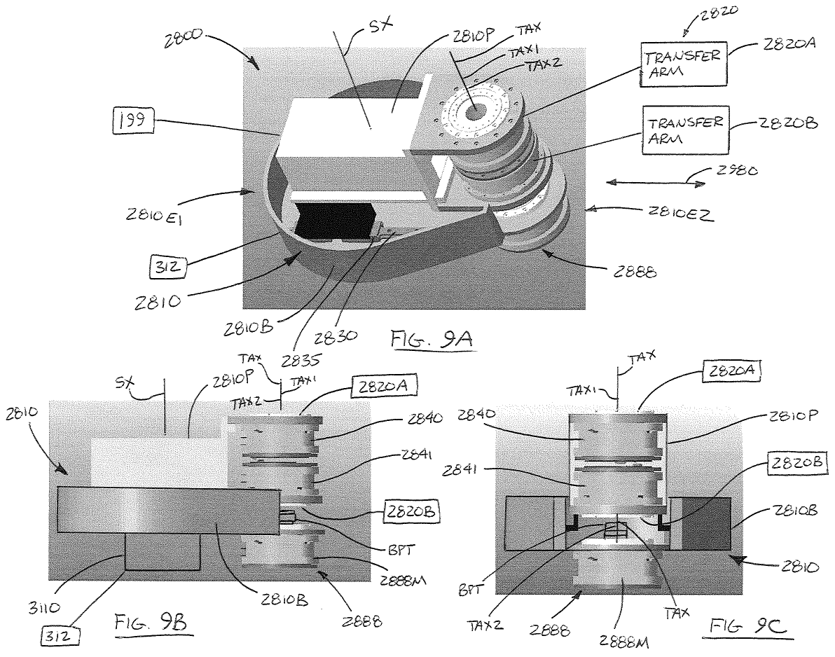

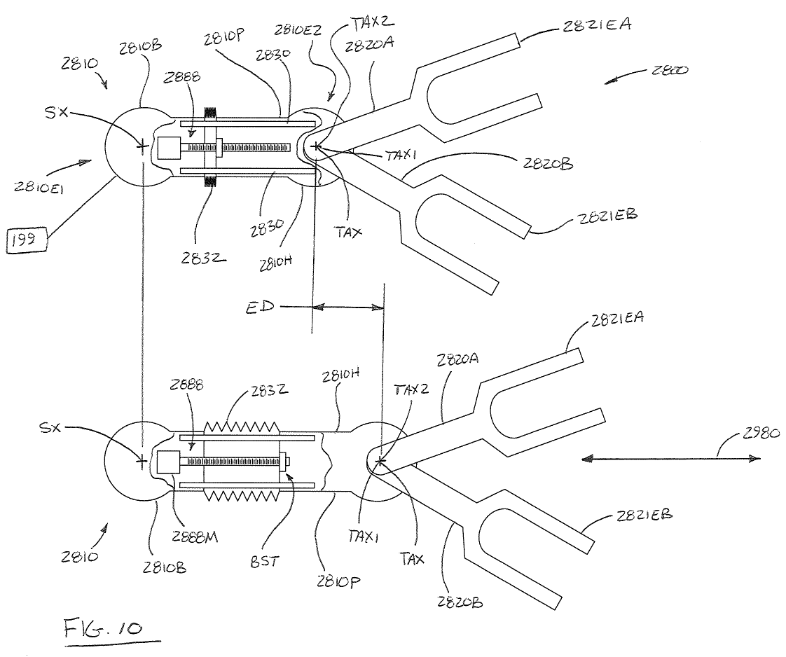

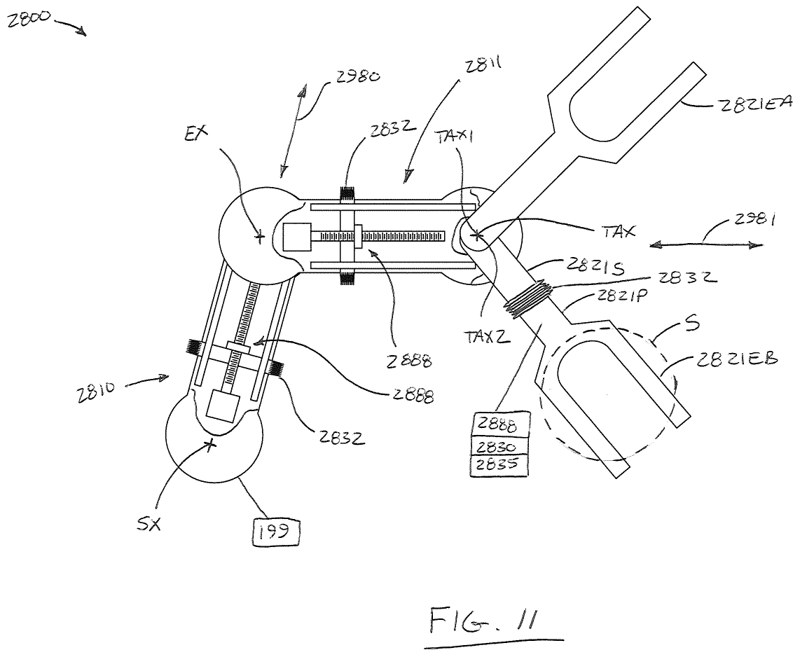

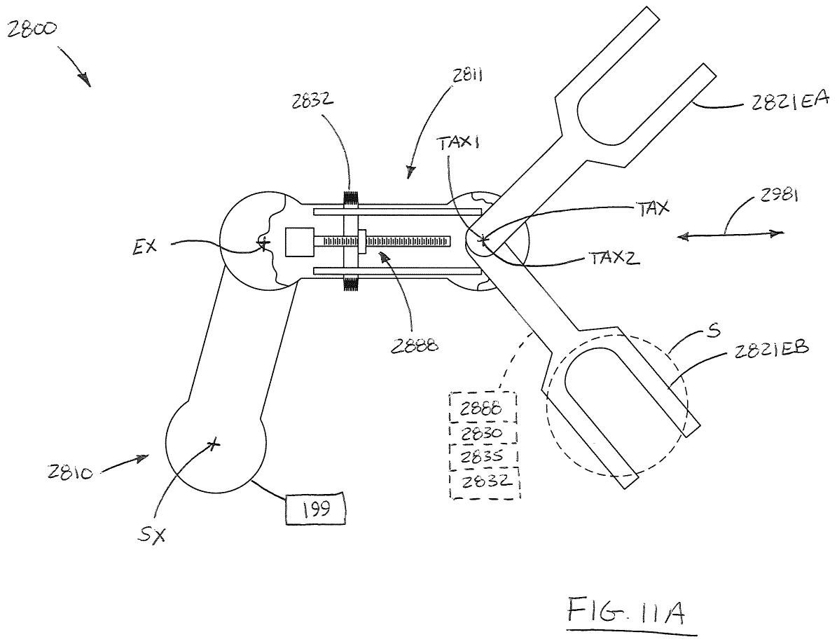

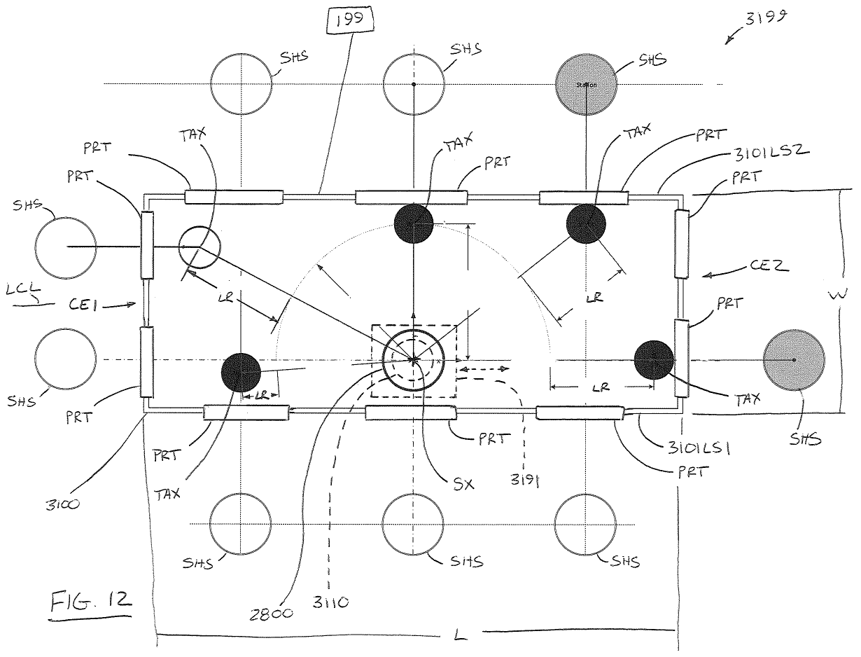

Referring to FIGS. 9A-9C and 10, a portion of a substrate transport apparatus 2800 is illustrated. It is noted the features described with respect to substrate transport apparatus 2800 may be applied to any one or all of the substrate transport apparatus described herein. Also with reference to FIG. 12, the substrate transport apparatus 2800 is configured for operation in any suitable transport chamber 3100 of a substrate processing apparatus 3199, such as those described herein. The transport chamber 3100 includes at least one lateral side 3101LS1, 3101LS2, where the at least one lateral side 1301LS1, 3101LS 2 has at least two (e.g., selectably sealable) substrate transport ports PRT arranged side by side (three substrate transport ports PRT are shown on each lateral side 1301LS1, 1301LS2 for exemplary purposes). The transport chamber 3100 includes ends CE1, CE2, where at least one lateral side 3101LS1, 3101LS2 extends between the ends CE1, CE2. One or more of the ends CE1, CE2 may include at least one substrate transport ports PRT. The transport chamber 3100 may be an equipment front end module or a transfer chamber for a process section (e.g., back end) of the substrate processing apparatus 3199 and configured to hold an atmospheric environment or a vacuum environment.

A drive section 3110 is connected to the transfer chamber 3100. The drive section 3110 has at least one motor defining at least one independent axis of rotation (e.g., axis SX, TAX1, TAX2). The drive section 3110 may be similar to those described herein and have a coaxial and/or distributed arrangement.

The substrate transport apparatus 2800 is mounted inside the transport chamber 3100. The drive section 3110, connected to or part of the substrate transport apparatus 2800, may be disposed within the transport chamber 3100 for removal of the substrate transport apparatus 2800 from the transport chamber 3100 as described herein. The substrate transport apparatus 2800 includes an upper arm link 2810 and at least one transfer arm 2820 (two transfer arms 2820A, 2820B are illustrated for exemplary purposes only). The upper arm link 2810 is operably coupled to the drive section 3110 and has a shoulder axis of rotation SX disposed at one end 2810E of the upper arm link 2810. The upper arm link 2810 is pivotally mounted inside the transport chamber 3100 at the shoulder axis of rotation SX located within the transport chamber 3100. The shoulder axis SX may be located at a fixed location within the transport chamber 3100 although, the shoulder axis may be mounted on a laterally traversing shuttle 3191 so as to move the shoulder axis SX between ends CE1, CE2 of the transport chamber 3100.

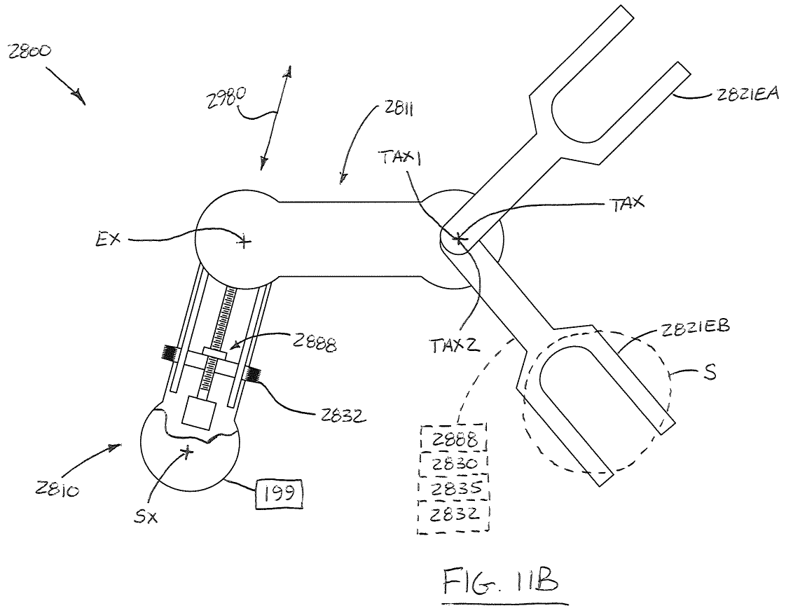

Each of the two transfer arms 2820A, 2820B (there may be more or less than two transfer arms) respectively have a corresponding one or more substrate holder 2821EA, 2821EB depending from the respective transfer arm 2820A, 2820B separate and distinct from each other transfer arm 2820A, 2820B (see, e.g., FIGS. 10 and 11). Each transfer arms 2820A, 2820B is pivotally mounted to another end 2810E2 of the upper arm link 3810 at another axis of rotation TAX. The other axis of rotation TAX is common a common axis of rotation, with respect to the upper arm link 2810, that is common to the two transfer arms 2820A, 2820B (again there may be more than two transfer arms 2820 pivotally mounted to the upper arm 2810 at the other axis of rotation TAX, the other axis of rotation TAX being common to the more than two transfer arms 2820).

Each of the transfer arms 2820A, 2820B is coupled to the drive section 3110 so that each transfer arm 2820A, 2820B respectively is coupled independently to and rotated independently by a different independent motor (see, e.g., depending on drive section configuration, the motors of FIGS. 4, 5, 6, and motors 2840, 2841 in FIGS. 9A-9C) from the at least one motor of the drive section 3110 (again the drive section may be similar to those described herein). For example, referring to FIGS. 9A-9C and 10 for non-limiting purposes of description, each transfer arm 2820A, 2820B may be coupled independently to and rotated independently by the different independent motor for independent rotation of each transfer arm 2820A, 2820B relative to another of the two transfer arms 2820A, 2820B about the common axis of rotation (e.g., the other axis of rotation TAX). For non-limiting purposes of description, transfer arm 2820A may be coupled independently to and rotated independently by motor 2840 about respective axis of rotation TAX1 and transfer arm 2820B may be coupled independently to and rotated independently by motor 2841 about respective axis of rotation TAX2, where the axes of rotation TAX1, TAX2 are coaxial so as to form the common/other axis of rotation TAX. The coupling of the respective transfer arm 2820A, 2820B to the different independent motor effects, with each respective transfer arm 2820A, 2820B, independent transport of substrates on the corresponding substrate holder 2821EA, 2821EB through each of the at least two substrate transport ports PRT arranged side by side (see FIG. 12).

The drive section 3110 may be a coaxial drive section (see, e.g., FIG. 4), or a distributed drive section (see, e.g., FIGS. 5, 6, and 9A-9C). The drive section may include a Z-axis or lift motor 312 similar to that described herein with respect to, e.g., FIGS. 2-4, 5, and 6. The distributed drive section may include drive portions that have coaxial drive motor arrangements and direct drive motor arrangements although the drive portions may include only direct drive motor arrangements. Where the drive section 3110 has a distributed configuration, part of the drive section 3110 (with reference to FIGS. 9A-9C for exemplary purposes only, but see also FIGS. 5 and 6) may be dependent from the upper arm link 2810 in a sealed housing 2810H with the different independent motor 2840, 2841 independently rotating the respective transfer arm 2820A, 2820B, at the other axis of rotation TAX, housed in the sealed housing 2810H. The sealed housing 2810H may be formed by the upper arm link 2810 as described herein.

At least the upper arm link 2810 may be articulated so that a translation portion 2810P of the upper arm link 2810 extends and retracts linearly between the shoulder axis of rotation SX and the other axis TAX. The upper arm 2810 includes a base portion 2810B having the shoulder axis of rotation SX and the translation portion 2810P having the other axis of rotation TAX. The translation portion 2810P may be movably connected to the base portion 2810B in any suitable manner, such as by a prismatic joint, so as to linearly translate relative to the base portion 2810B. As a non-limiting example, one or more guide rails 2830 may be coupled to and extend from the base portion 2810B. The translation portion 2810P may include one or more slides 2835 that slidingly engage a respective guide rail of the one or more guide rails 2830 so that the translation portion 2810P slides along the respective guide rail in a translation direction 2980. While guide rails 2830 are described herein, any suitable movable coupling may be employed including, but not limited to, guide rods and telescoping rods/rails.

To articulate at least the upper arm link 2810, the drive section 3110 may include a linear drive 2888. The linear drive 2888 has another motor 2888M that is separate and distinct from each of the different independent motor (see, e.g., depending on drive section configuration, the motors of FIGS. 4, 5, 6, and motors 2840, 2841 in FIGS. 9A-9C), where each different independent motor 2840, 2841 (referring to FIGS. 9A-9C for convenience only, noting again depending on drive configuration this description is applicable to the motors of FIGS. 4, 5, and 6 as well) respectively defines a corresponding independent axis of rotation TAX1, TAX2, SX of the at least one independent axis of rotation (e.g., TAX1, TAX2, SX). The linear drive 2888 may be any suitable linear drive including, but not limited to a belt/band and pulley linear drive (where motor 2888M of the linear drive 2888 drives a belt and pulley transmission BPT-see FIGS. 9A-9C), a ball screw drive (where motor 2888M drives a ball screw of a ball screw transmission BST-see FIG. 10), an electronic linear actuator, a pneumatic linear actuator, a hydraulic linear actuator, or any other suitable motor/transmission configured to effect linear movement. The linear drive 2888 may include any suitable position feedback (e.g., encoders, etc.) for positioning the other axis of rotation TAX effecting extension/retraction of the substrate transport apparatus 2800. The linear drive 2888 position feedback may also effect adjusting a length of the upper arm link 2810 to compensate for thermal expansion of the upper arm link 2810.

The upper arm link 2810 may include any suitable seal 2832 that seals the linear drive from an environment outside the upper arm link 2810. The seal 2832 may, at least in part, seal the motors 2840, 2841 from the environment outside the upper arm link 2810. The seal 2832 is illustrated in FIG. 10 as a bellows seal for exemplary purposes only although, any seal configured to provide a seal between sliding components may be employed.

The upper arm link 2810 may be configured (such as described herein) so as to extend and retract the other axis of rotation TAX, relative to the shoulder axis of rotation SAX, and position the other axis of rotation TAX juxtaposed each substrate transport port PRT of the at least two substrate transport ports PRT in the at least one lateral side 3101LS1, 3101LS2 of the transport chamber 3100. The upper arm link 2810 may be configured (such as described herein) so as to extend and retract the other axis of rotation TAX, relative to the shoulder axis of rotation SAX, and position the other axis of rotation TAX juxtaposed each substrate transport port PRT in a respective one or more of the ends CE1, CE2 of the transport chamber 3100. Placement of the other axis of rotation TAX juxtaposed one or more of the substrate transport port PRT in the lateral side(s) 3101LS1, 3101LS2 and/or the end(s) CE1, CE2 may be effected by combination of rotation of the upper arm link 2810 about the shoulder axis of rotation SAX and extension/retraction of the other axis of rotation TAX.

As described, at least the upper arm link 2810 may be articulated. Referring to FIG. 11, an exemplary substrate transport apparatus 2800 is illustrated as having the upper arm link 2810, a forearm link 2811 that is rotatably coupled to the upper arm link 2810 at an elbow axis EX, and the two substrate holders 2821EA, 2821EB are rotatably coupled to the forearm link 2811 at the other axis of rotation TAX. The upper arm link 2810 is as described above however, here the upper arm link linearly extends/retracts (or otherwise articulates) the elbow axis of rotation EX in direction 2980 (i.e., along a longitudinal axis of the upper arm link 2810). The forearm link 2811 includes a linear drive 2888, similar to that of the upper arm link, such that the forearm link is configured to extend and retract the other axis of rotation in direction 2981 (i.e., along a longitudinal axis of the forearm link 2811). While both the upper arm link 2810 and forearm link 2811 are illustrated as having the linear drive 2888 and being articulated for linear extension/retraction, the upper arm link 2810 may be configured for linear extension/retraction while the forearm link 2811 is unarticulated (illustrated in FIG. 11B), or the upper arm link 2810 may be unarticulated while the forearm link 2811 is articulated (illustrated in FIG. 11A).

One or more of the substrate holders 2821EA, 2821EB may be articulated in a manner similar to that of the upper arm link. For example, with reference to FIG. 11, one or more of the substrate holders 2821EA, 2821EB may be an articulated substrate holder having a base portion 2821S having the other axis of rotation TAX and a translation portion 2821P configured to hold a substrate S. The one or more of the substrate holders 2821EA, 2821EA may include the guide rails 2830, slides 2835 and linear drive 2888 so that the translation portion 2821P is driven, by the linear drive 2888, to extend/retract relative to the base portion 2821S.

The linearly extending upper arm link 2810, linearly expanding forearm link 2811, and/or linearly expanding substrate holder 2821EA, 2821EB may provide for longer substrate transport arm extensions for a minimized arm containment (i.e., the reach to containment ratio of the substrate transport arm is maximized). For example, the referring to FIG. 12, the shoulder axis SX of the substrate transport apparatus 2800 may be mounted within the transport chamber 3100 at a location that is offset from a longitudinal centerline LCL of the transport chamber 3100, such that with the substrate transport apparatus 2800 in a retracted configuration there is only minimal clearance (e.g., only sufficient clearance to allow unhindered movement of the transport arm and wafer thereon) between the lateral side 3101LS1, 3101LS2 walls of the transport chamber 3100 and the substrate transport apparatus 2800 (see FIG. 12 where the shoulder axis SX is adjacent lateral side 3101LS1 and the other axis of rotation is adjacent lateral side 3101LS2). In FIG. 12 a traverser or laterally traversing shuttle 3191 may be provided so as to position the shoulder axis SX for extension of the substrate holder 2821EA, 2821EB into each of the substrate transport ports PRT although, the linearly extending upper arm link 2810, linearly expanding forearm link 2811, and/or linearly expanding substrate holder 2821EA, 2821EB may provide for a reduced travel of the laterally traversing shuttle 3191 between the ends CE1, CE2 of the transport chamber 3100. As an example, a linear extension distance ED (see FIG. 10) of the upper arm link 2810, linearly expanding forearm link 2811, and/or linearly expanding substrate holder 2821EA, 2821EB may be between about 185 mm and about 520 mm although, the linear extension distance ED may be more than about 520 mm or less than about 185 mm. Providing the laterally traversing shuttle 3191 may provide for reducing the linear extension distance ED. To reach what may be referred to as long reach substrate holding stations, the upper arm link 2810, linearly expanding forearm link 2811, and/or linearly expanding substrate holder 2821EA, 2821EB may linearly extend a long reach distance LR (see FIG. 12) as the substrate transport arm 2800 extends for picking/placing substrate to the substrate holding stations SHS.

The one or more linearly extendable arm links may provide for telescoping linkages with substantially no kinematic singularities, minimal dynamic coupling, scalar link lengths to compensate for thermal expansion of the arm links, and the minimized containment to reach ratio. The one or more linearly extendable arm links may provide for reduced transport chamber 3100 width W and/or increased length L (e.g., based on the minimized containment to reach ratio) for high density substrate processing tools.

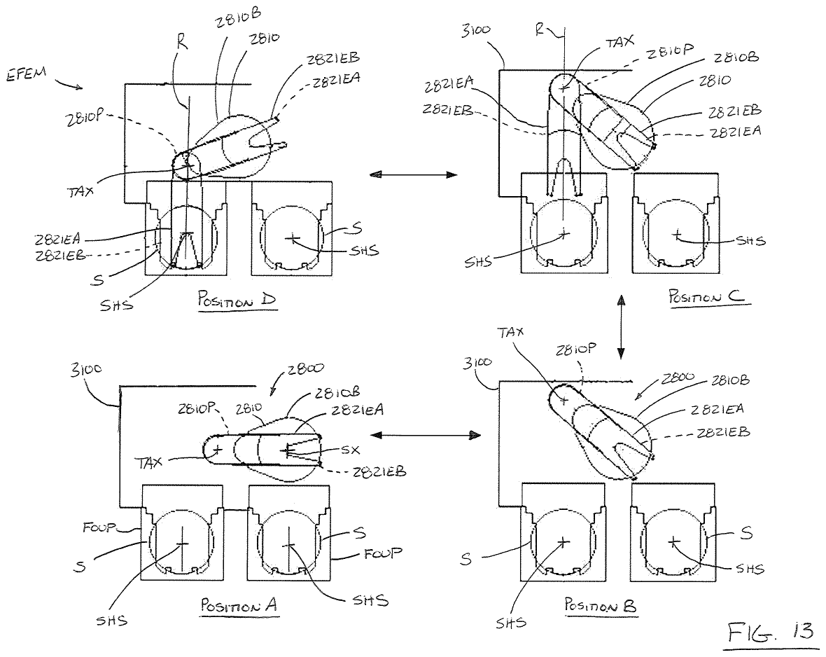

Referring to FIGS. 9A-12 and 13, and exemplary transport trajectory for the substrate transport apparatus 2800, under control of any suitable controller such as the controller 199 (e.g., the controller 199 is configured to effect operation of the substrate transport arm 2800 as described herein), will be described. To pick, place, and/or swap one or more substrates S at a substrate holding stations SHS, the substrate transport apparatus 2800 is positioned (e.g., by one or more of the shuttle 3191 and linear extension/retraction of the upper arm link 2810) so that the other axis of rotation TAX is disposed adjacent a desired (predetermined/selected) substrate holding station SHS (see Position A in FIG. 13). The substrate holding station SHS may be any suitable substrate holding station such as a substrate carrier (e.g., FOUP) disposed at a load port of the transport chamber 3100, a process station, a load lock, etc. and is illustrated as a FOUP for exemplary purposes only. The drive section 3110 rotates the upper arm link 3810 and/or extends/retracts the upper arm link 3810 so that the upper arm link 3810 and substrate holder(s) 2821EA, 2821EB are oriented for picking, placing, or swapping one or more substrates S (see Position B in FIG. 13). The drive section 3110 rotates one or more of the substrate holders 2821EA, 2821EB and postures the substrate transport apparatus 2800 for a pick/place/swap of one or more substrates S (see Position C in FIG. 13). The drive section 3110 one or more of rotates the upper arm link 2810 about the shoulder axis SX, linearly extends/retracts the upper arm link 2810, and rotates the one or more substrate holders 2821EA, 2821EB about the other axis of rotation TAX so that the other axis of rotation TAX follows a straight line or radial path R through the port PRT of (into/out of) the desired substrate holding station SHS (see Position D in FIG. 13). To remove the substrate S from the substrate holding station SHS, the controller 199 commands the drive section 3110 to move the substrate transport apparatus back to position B (FIG. 13) so that the substrate transport apparatus 2810 may transport the picked substrate S to another desired/predetermined substrate holding station SHS. To swap substrates S, the controller 199 commands the drive section 3110 to move the substrate transport apparatus (e.g., from Position D along the radial path R to Position B in FIG. 13) to remove the picked substrate S from the substrate holding station SHS, so that another of the substrate holders 2821EA, 2821EB may be moved through the port PRT into the substrate holding station SHS (see Positions C and D in FIG. 13) for placing a substrate S.

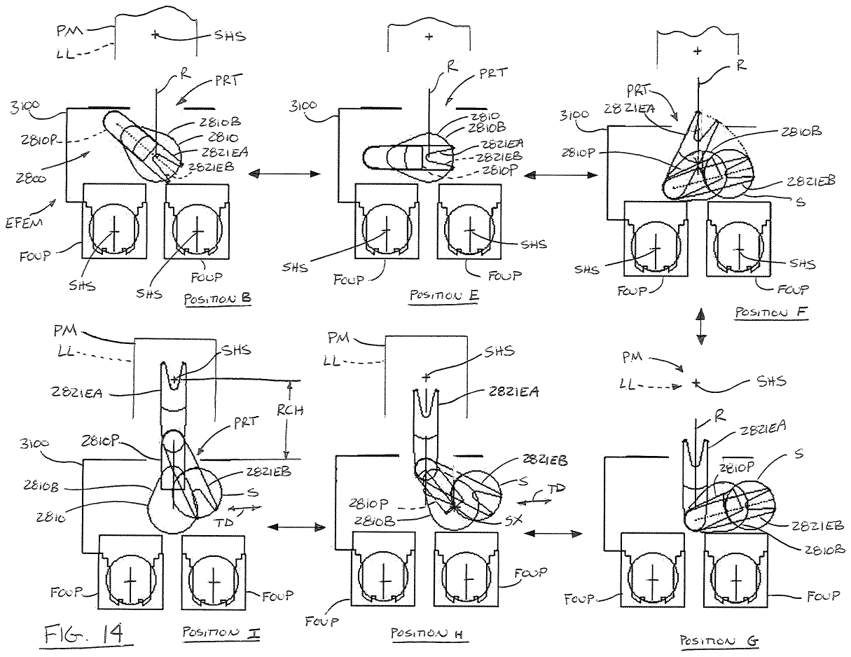

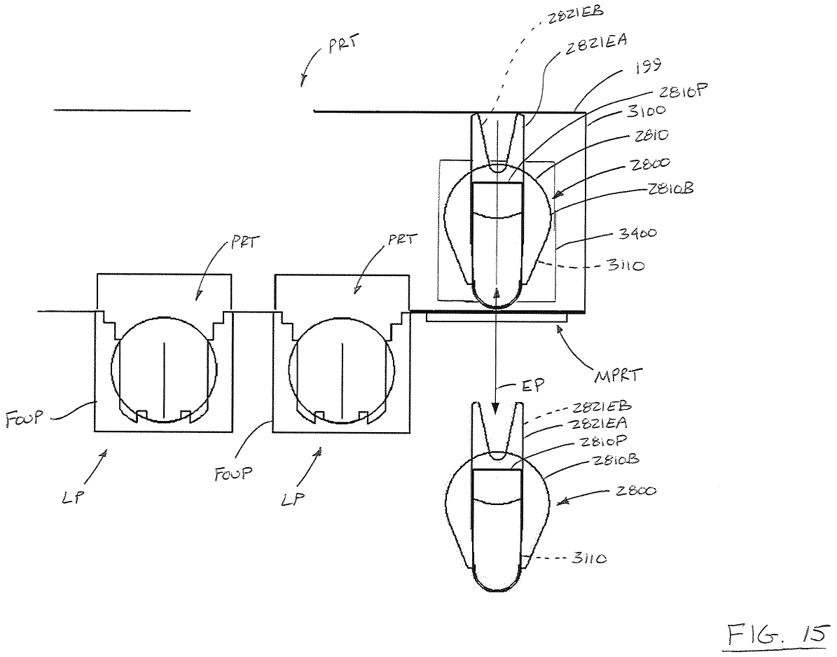

Referring also to FIG. 14, with a substrate removed from a FOUP, the controller 199 may command the substrate transport apparatus 2800 to swap the picked substrate S from the FOUP (or other substrate holding stations SHS) with a substrate held at a process module PM or load lock LL. As described above, when swapping substrates at a FOUP (or other substrate holding station SHS) the controller 199 commands the drive section 3110 to move the substrate transport apparatus (e.g., from Position D along the radial path R to Position B in FIG. 13) to remove the picked substrate S or empty substrate holder 2821EA, 2821EB from the FOUP so that the substrate transport apparatus 2800 is disposed at position B (see FIGS. 13 and 14). The controller 199 commands movement of the substrate transport apparatus so that a substrate support station SSS of the substrate holder 2821EA (or substrate holder 2821EB) is aligned with a radial extension/retraction path R through the port PRT corresponding to the process module PM or load lock LL (see Position E in FIG. 14). The controller 199 commands the drive section 3110 to rotate the substrate holder 2821EA (or substrate holder 2821EB) and move the upper arm link 2810 (e.g., in one or more of rotation, traverse, and extension) so that a longitudinal axis of the substrate holder 2821EA (or substrate holder 2821EB) is aligned with the radial extension/retraction path R (see Positions F and G in FIG. 14). The other substrate holder 2821EB (or substrate holder 2821EA) is rotated so as to remain in a retracted configuration (see Positions F and G in FIG. 14). With the substrate holder 2821EA (or substrate holder 2821EB) aligned with the radial extension/retraction path R, the controller 199 commands the drive section 3110 to extend the substrate holder 2821EA along the radial extension/retraction path R in a radial movement (e.g., with the substrate holder remaining aligned with the radial extension/retraction path R throughout the extension), where the upper arm link 2810 is one or more of driven in rotation about the shoulder axis SX and translated in direction TD (see Positions H and I in FIG. 14). The controller 199 commands the translation portion 2810P of the upper arm link 2810 to linearly extend relative to the base portion 2810B of the upper arm link 2810 so as to provide the substrate transport apparatus 2800 with a reach RCH of about 450 mm (the reach may be greater or less than 450 mm) from the side (such as a lateral side 3101LS1, 3101LS2 or end CE1, CE2 of the transport chamber 3100) (see Position I in FIG. 14). Removal of a substrate S or substrate holder 2821EA (or substrate holder 2821EB) may be effected in the reverse manner to that described above. Referring to FIG. 15, the configuration of the substrate transport arm 2800 may facilitate removal of the substrate transport arm 2800 (in a retracted configuration as shown in FIG. 15) through a suitable port, such as (e.g., selectably sealable) maintenance port MPRT of the transport chamber 3100, for maintenance of the substrate transport arm 2800. For example, the minimized arm containment may provide for longitudinal alignment of the substrate holders 2821EA, 2821EB and upper arm link 2810 with a transport ingress/egress path EP through the maintenance port MPRT. The drive section 3110 may be connected to the substrate transport apparatus in a configuration that provides for passage of the drive section 3110, upper arm link 2810 (and forearm link where provided), and substrate holders 2821EA, 2821EB through the maintenance port MPRT as a unit. The maintenance port MPRT may be sized and shaped similar to the port PRT of a load port LP (such as of an equipment front end module or EFEM) that engages a FOUP although, the maintenance port MPRT may have any suitable size and shape. The transport chamber 3100 may include a transport apparatus positioning mechanism 3400 that may be configured to tilt or otherwise lift the substrate transport apparatus 2800 so that an operator (human or automated machinery) may remove or insert the substrate transport apparatus 2800 from or to the transport chamber 3100 through the maintenance port MPRT. The transport apparatus positioning mechanism 3400 may be configured to traverse (such as on a slide) the substrate transport apparatus 2800 through the maintenance port MPRT for removal or insertion of the substrate transport apparatus 2800 from or to the transport chamber 3100. The substrate transport apparatus 2800 and its drive section 3110 may have a plug and play configuration such that removal of the substrate transport apparatus 2800 from the transport chamber 3100 through the maintenance port MPRT may automatically decouples controls connections (e.g., electrical connections, pneumatic connections, communications connections, etc.) of the substrate transport apparatus 2800 from corresponding controls connections of the transport chamber 3100. Insertion/installation of the substrate transport apparatus 2800 to the transport chamber 3100 through the maintenance port MPRT may automatically operably couple the controls connections (e.g., electrical connections, pneumatic connections, communications connections, etc.) of the substrate transport apparatus 2800 to the corresponding controls connections of the transport chamber 3100.

Referring to FIGS. 9A-15, and 16, an exemplary method will be described. The method includes providing a substrate processing apparatus (FIG. 16, Block 3500) such as those described herein. For non-limiting purposes of explanation of the method, the substrate processing apparatus 3199 will be referred to. The substrate processing apparatus 3199 may include a transport chamber 3100 having at least one lateral side 3101LS1, 3101LS2, where the at least one lateral side 1301LS1, 3101LS2 has at least two (e.g., selectably sealable) substrate transport ports PRT arranged side by side (three substrate transport ports PRT are shown on each lateral side 1301LS1, 1301LS2 for exemplary purposes). The substrate processing apparatus 3199 may have a drive section 3110 connected to the transfer chamber 3100. The drive section 3110 has at least one motor defining at least one independent axis of rotation (e.g., axis SX, TAX1, TAX2). The substrate processing apparatus 3199 may include a substrate transport apparatus 2800 is mounted inside the transport chamber 3100. The substrate transport apparatus 2800 includes an upper arm link 2810 and at least one transfer arm 2820 (two transfer arms 2820A, 2820B are illustrated for exemplary purposes only). The upper arm link 2810 is operably coupled to the drive section 3110 and has a shoulder axis of rotation SX disposed at one end 2810E of the upper arm link 2810. The upper arm link 2810 is pivotally mounted inside the transport chamber 3100 at the shoulder axis of rotation SX located within the transport chamber 3100. Each of the two transfer arms 2820A, 2820B (there may be more or less than two transfer arms) respectively have a corresponding substrate holder 2821EA, 2821EB depending from the respective transfer arm 2820A, 2820B separate and distinct from each other transfer arm 2820A, 2820B (see, e.g., FIGS. 10 and 11). Each transfer arms 2820A, 2820B is pivotally mounted to another end 2 810E2 of the upper arm link 3810 at another axis of rotation TAX. The other axis of rotation TAX is common a common axis of rotation, with respect to the upper arm link 2810, that is common to the two transfer arms 2820A, 2820B (again there may be more than two transfer arms 2820 pivotally mounted to the upper arm 2810 at the other axis of rotation TAX, the other axis of rotation TAX being common to the more than two transfer arms 2820). Each of the transfer arms 2820A, 2820B is coupled to the drive section 3110 so that each transfer arm 2820A, 2820B respectively is coupled independently to and rotated independently by a different independent motor (see, e.g., depending on drive section configuration, the motors of FIGS. 4, 5, 6, and motors 2840, 2841 in FIGS. 9A-9C) from the at least one motor of the drive section 3110 (again the drive section may be similar to those described herein).

The method includes linearly articulating the upper arm link 2810 (FIG. 16, Block 3510) so that a translation portion 2810P of the upper arm link 2810 extends and retracts linearly between the shoulder axis of rotation SX and the other axis of rotation TAX.

The method may include one or more of the following, individually, in any combination thereof, and/or in any combination with the features described herein: the drive section 3110 includes a linear drive 2888 with another motor 2888M separate and distinct from each of the different independent motor (see, e.g., depending on drive section configuration, the motors of FIGS. 4, 5, 6, and motors 2840, 2841 in FIGS. 9A-9C), and each different independent motor 2840, 2841 (referring to FIGS. 9A-9C for convenience only, noting again depending on drive configuration this description is applicable to the motors of FIGS. 4, 5, and 6 as well) respectively defines a corresponding independent axis of rotation TAX1, TAX2, SX of the at least one independent axis of rotation (e.g., TAX1, TAX2, SX); the upper arm link 2810 includes a seal 2832 that seals the linear drive 2888 from an environment outside the upper arm link 2810; the drive section 3110 has a distributed configuration with part of the drive section 3110 dependent from the upper arm link 2810 in a sealed housing 2810H with the different independent motor 2840, 2841 independently rotating the respective transfer arm 2820A, 2820B, at the other axis of rotation TAX, housed in the sealed housing 2810H; each transfer arm 2820A, 2820B is coupled independently to and rotated independently by the different independent motor 2840, 2841 for independent rotation of each transfer arm 2820A, 2820B relative to another of the two transfer arms 2820A, 2820B about the common axis of rotation TAX, and effecting with each respective transfer arm 2820A, 2820B independent transport of substrates S on the corresponding substrate holder 2821EA, 2821EB through each of the at least two substrate transport ports PRT arranged side by side; the upper arm 2810 is extends and retracts the other axis of rotation TAX, relative to the shoulder axis SX, and positions the other axis of rotation TAX juxtaposed each substrate transport port PRT of the at least two substrate transport port PRT in the at least one lateral side 3101LS1, 3101LS2; the shoulder axis SX is located at a fixed location within the transport chamber 3100, and a single side of the at least one lateral side 3101LS1, 3101LS2 has three substrate transport ports PRT arranged side by side; and the shoulder axis SX is mounted on a laterally traversing shuttle 3191, and the transport chamber 3100 is an equipment front end module EFEM.

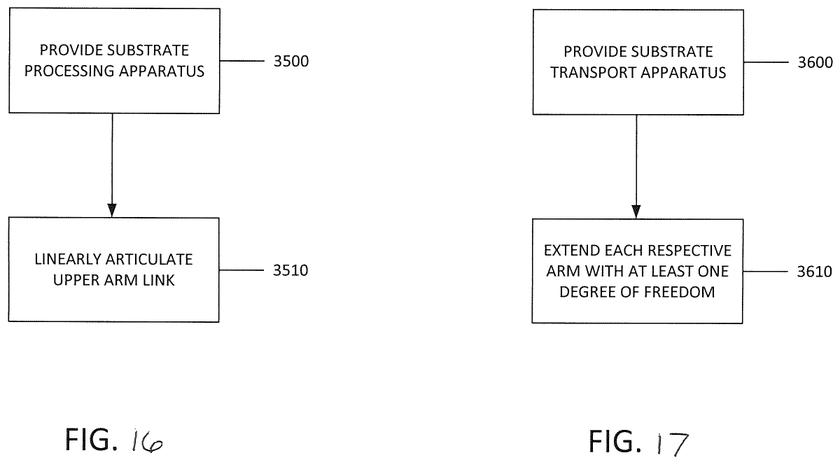

Referring to FIGS. 5-8B and 17, an exemplary method will be described. The method includes providing the robot assembly or substrate transport apparatus 10F, 10G (FIG. 17, Block 3600). As described herein, the robot assembly 10F, 10G includes a frame 2401 and the base link or hub 2420 is pivotally joined to the frame 2401 so as to rotate relative to the frame 2401 about a base pivot joint axis of rotation HX fixed to the frame 2401. A pair of dual arms PDA having first dual arms PDA1 and second dual arms PDA2. The first dual arms PDA1 are juxtaposed with respect to the second dual arms PDA2. The first dual arms PDA have a first top arm 2401A with a first top end effector 2402E, and a first bottom arm 2401B with a first bottom end effector 2402E. The second dual arms PDA2 have a second top arm 2401D with a second top end effector 2402E, and a second bottom arm 2401C with a second bottom end effector 2402E.

The first top arm 2401A has a corresponding top terminal joint SX, and the first bottom arm 2401B has a corresponding bottom terminal joint SX. Each of the first top arm 2401A and the first bottom arm 2401B respectively rotates and extends from the corresponding top terminal joint SX and bottom terminal joint SX. The top terminal and bottom terminal joint SX being coaxial and respectively joining each first top and bottom arm 2401A, 2401B to the base link 2420 via the corresponding top terminal joint and bottom terminal joint SX. The first top arm 2401A has at least one first top arm link 2402U, 2402F and the first top end effector 2402E is dependent from a top distal link (e.g., forearm link 2402F) of the first top arm 2401A. The first bottom arm 2401B has at least one bottom arm link 2402U, 2402F and the first bottom end effector 2402E is dependent from a bottom distal link (e.g., forearm link 2402F) of the first bottom arm 2401B. Each arm link of the first top arm 2401A is separate and distinct from each arm link of the first bottom arm 2401B, and the first top and bottom end effector 2402E extend overlapping each other at least in part.

Each respective arm 2401A-2401D is extended with at least one degree of freedom (FIG. 17, Block 3610), by the drive section 2400 which has at least one motor 2400S, 2400U, 2400E (see FIGS. 5 and 6) connected to each respective arm 2401A,-2401D, of the pair of dual arms PDA, independent of each other respective arm 2401A-2401D of the pair of dual arms PDA, where the drive section 2400 has at least another motor 2400H, 2400L connected to the base link 2420 so as to rotate the base link 2420 about the base pivot joint axis of rotation HX so that each corresponding end effector 2402E of the respective arm 2401A-2401D is extended and rotated along a substantially level substrate transport plane TP.

Each respective top arm 2401A, 2401D of the first and second dual arms PDA1, PDA2, or each respective bottom arm 2401B, 201C of the first and second dual arms PDA1, PDA2, are arranged to: effect substantially simultaneous dual extension and retraction with juxtaposed moves of the respective first top arm 2401A and second top arm 2401D, or the respective first bottom arm 2401B and second bottom arm 2401C; and effect extension and retraction of at least the first top arm 2401A or the second top arm 2401D along a radial path R extending from the base pivot joint axis of rotation HX.

The method may include one or more of the following, individually, in any suitable combination thereof, and/or in any suitable combination with the features described herein: The frame 2401 may be a chamber 2401CH (such as, e.g., any suitable transfer chamber or other chamber as described herein, only a portion of which is illustrated in FIGS. 5 and 6) arranged to hold a sealed atmosphere SATM therein; the at least one motor 2400U, 2400S, 2400E may be located within the sealed atmosphere SATM of the chamber, housed in a sealed housing (such as formed by one or more of: the base link or hub 2420, arm link(s) 2402U of one or more of the arms 2401A-2401D, and arm link(s) 2402F of one or more of the arms 2401A-2401D) sealed from the sealed atmosphere, where the sealed housing seals a rotor R and/or stator S of the at least one motor 2400S, 2400U, 2400E from the sealed atmosphere SATM; the at least one other motor 2400H, 2400L of the drive section 2400 may include more than one other motor 2400H, 2400L, each coupled to the base link 2420 and arranged so that the base link rotation about the base pivot joint axis of rotation HX has more than one degree of freedom; and the base link 2420 may be configured so that the more than one degree of freedom are each disposed to effect rotation and extension, along the radial path R, of the first top arm 2401A and the second top arm 2401D decoupled from rotation and extension, along the radial path R, of the first bottom arm 2401B and second bottom arm 2401C.

The following features of the present disclosure are provided and may be employed individually, in any combination with each other, and/or in any combination with the features described above.

A substrate processing apparatus comprises: a transport chamber having at least one lateral side, the at least one lateral side having at least two substrate transport ports arranged side by side; a drive section connected to the transport chamber, the drive section having at least one motor defining at least one independent axis of rotation; and a substrate transport apparatus mounted inside the transport chamber, the substrate transport apparatus including: an upper arm link being operably coupled to the drive section and having a shoulder axis of rotation disposed at one end of the upper arm link, the upper arm link being pivotally mounted inside the transport chamber at the shoulder axis of rotation located within the transport chamber, and at least one transfer arm, each transfer arm respectively having a corresponding substrate holder depending from the respective transfer arm separate and distinct from each other transfer arm, and each transfer arm being pivotally mounted to another end of the upper arm link at another axis of rotation, the other axis of rotation being a common axis of rotation, with respect to the upper arm link, that is common to the at least one transfer arm; and wherein the upper arm link is linearly articulated, so that a translation portion of the upper arm link extends and retracts linearly between the shoulder axis of rotation and the other axis of rotation, and each transfer arm is coupled to the drive section so that each transfer arm respectively is coupled independently to and rotated independently by a different independent motor from the at least one motor of the drive section.

The substrate processing apparatus may include one or more of the following individually, in any combination with each other, and/or in any combination with the features described herein: the drive section includes a linear drive with another motor separate and distinct from each of the different independent motor, and each different independent motor respectively defines a corresponding independent axis of rotation of the at least one independent axis of rotation; the upper arm link includes a seal that seals the linear drive from an environment outside the upper arm link; the upper arm link includes a prismatic joint joining one or more of the at least one transfer arm to the upper arm link; the drive section has a distributed configuration with part of the drive section dependent from the upper arm link in a sealed housing with the different independent motor independently rotating the respective transfer arm, at the other axis of rotation, housed therein; each transfer arm is coupled independently to and rotated independently by the different independent motor for independent rotation of each transfer arm relative to another of the at least one transfer arm about the common axis of rotation, and effecting with each respective transfer arm independent transport of substrates on the corresponding substrate holder through each of the at least two substrate transport ports arranged side by side; the upper arm link is configured so as to extend and retract the other axis of rotation, relative to the shoulder axis, and position the other axis of rotation juxtaposed each substrate transport port of the at least two substrate transport ports in the at least one lateral side; the shoulder axis is located at a fixed location within the transport chamber, and a single side of the at least one lateral side has three substrate transport ports arranged side by side; and the shoulder axis is mounted on a laterally traversing shuttle, and the transport chamber is an equipment front end module.

A method comprises: providing a substrate processing apparatus including: a transport chamber having at least one lateral side, the at least one lateral side having at least two substrate transport ports arranged side by side; a drive section connected to the transport chamber, the drive section having at least one motor defining at least one independent axis of rotation; and a substrate transport apparatus mounted inside the transport chamber, the substrate transport apparatus including: an upper arm link being operably coupled to the drive section and having a shoulder axis of rotation disposed at one end of the upper arm link, the upper arm link being pivotally mounted inside the transport chamber at the shoulder axis of rotation located within the transport chamber, and at least one transfer arm, each transfer arm respectively having a corresponding substrate holder depending from the respective transfer arm separate and distinct from each other transfer arm, and each transfer arm being pivotally mounted to another end of the upper arm link at another axis of rotation, the other axis of rotation being a common axis of rotation, with respect to the upper arm link, that is common to the at least one transfer arm; where each transfer arm is coupled to the drive section so that each transfer arm respectively is coupled independently to and rotated independently by a different independent motor from the at least one motor of the drive section; and linearly articulating the upper arm link so that a translation portion of the upper arm link extends and retracts linearly between the shoulder axis of rotation and the other axis of rotation.

The method may include one or more of the following individually, in any combination with each other, and/or in any combination with the features described herein: the drive section includes a linear drive with another motor separate and distinct from each of the different independent motor, and each different independent motor respectively defines a corresponding independent axis of rotation of the at least one independent axis of rotation; the upper arm link includes a seal that seals the linear drive from an environment outside the upper arm link; the upper arm link includes a prismatic joint joining one or more of the at least one transfer arm to the upper arm link; the drive section has a distributed configuration with part of the drive section dependent from the upper arm link in a sealed housing with the different independent motor independently rotating the respective transfer arm, at the other axis of rotation, housed therein; each transfer arm is coupled independently to and rotated independently by the different independent motor for independent rotation of each transfer arm relative to another of the at least one transfer arm about the common axis of rotation, and effecting with each respective transfer arm independent transport of substrates on the corresponding substrate holder through each of the at least two substrate transport ports arranged side by side; the upper arm is extends and retracts the other axis of rotation, relative to the shoulder axis, and positions the other axis of rotation juxtaposed each substrate transport port of the at least two substrate transport port in the at least one lateral side; the shoulder axis is located at a fixed location within the transport chamber, and a single side of the at least one lateral side has three substrate transport ports arranged side by side; and the shoulder axis is mounted on a laterally traversing shuttle, and the transport chamber is an equipment front end module.

A substrate transport apparatus comprises: a frame; a base link pivotally joined to the frame so as to rotate relative to the frame about a base pivot joint axis of rotation fixed to the frame; a pair of dual arms having first dual arms and second dual arms, the first dual arms are juxtaposed with respect to the second dual arms, the first dual arms have a first top arm with a first top end effector, and a first bottom arm with a first bottom end effector, and the second dual arms have a second top arm with a second top end effector, and a second bottom arm with a second bottom end effector; the first top arm has a corresponding top terminal joint, and the first bottom arm has a corresponding bottom terminal joint, each of the first top arm and the first bottom arm respectively rotates and extends from the corresponding top terminal joint and bottom terminal joint, the top terminal and bottom terminal joint being coaxial and respectively joining each first top and bottom arm to the base link via the corresponding top terminal joint and bottom terminal joint, the first top arm has at least one first top arm link and the first top end effector dependent from a top distal link of the first top arm, and the first bottom arm has at least one bottom arm link and the first bottom end effector dependent from a bottom distal link of the first bottom arm, each arm link of the first top arm being separate and distinct from each arm link of the first bottom arm, and the first top and bottom end effector extend overlapping each other at least in part; and a drive section with at least one motor connected to each respective arm, of the pair of dual arms, arranged to extend each respective arm with at least one degree of freedom, independent of each other respective arm of the pair of dual arms, and the drive section has at least another motor connected to the base link so as to rotate the base link about the base pivot joint axis of rotation so that each corresponding end effector of the respective arm is extended and rotated along a substantially level substrate transport plane; wherein each respective top arm of the first and second dual arms, or each respective bottom arm of the first and second dual arms, are arranged to: effect substantially simultaneous dual extension and retraction with juxtaposed moves of the respective first top arm and second top arm, or the respective first bottom arm and second bottom arm, and effect extension and retraction of at least the first top arm or the second top arm along a radial path extending from the base pivot joint axis of rotation.

The substrate processing apparatus may include one or more of the following individually, in any combination with each other, and/or in any combination with the features described herein: the frame is a chamber arranged to hold a sealed atmosphere; the at least one motor is located within the sealed atmosphere of the chamber, housed in a sealed housing sealed from the sealed atmosphere, where the sealed housing seals the rotor or stator of the at least one motor from the sealed atmosphere; the at least one other motor of the drive section includes more than one other motor, each coupled to the base link and arranged so that the base link rotation about the base pivot joint axis of rotation has more than one degree of freedom; and the base link is configured so that the more than one degree of freedom are each disposed to effect rotation and extension, along the radial path, of the first top arm and the second top arm decoupled from rotation and extension, along the radial path, of the first bottom arm and second bottom arm.

A method comprises: providing a substrate transport apparatus including: a frame; a base link pivotally joined to the frame so as to rotate relative to the frame about a base pivot joint axis of rotation fixed to the frame; a pair of dual arms having first dual arms and second dual arms, the first dual arms are juxtaposed with respect to the second dual arms, the first dual arms have a first top arm with a first top end effector, and a first bottom arm with a first bottom end effector, and the second dual arms have a second top arm with a second top end effector, and a second bottom arm with a second bottom end effector; and the first top arm has a corresponding top terminal joint, and the first bottom arm has a corresponding bottom terminal joint, each of the first top arm and the first bottom arm respectively rotates and extends from the corresponding top terminal joint and bottom terminal joint, the top terminal and bottom terminal joint being coaxial and respectively joining each first top and bottom arm to the base link via the corresponding top terminal joint and bottom terminal joint, the first top arm has at least one first top arm link and the first top end effector dependent from a top distal link of the first top arm, and the first bottom arm has at least one bottom arm link and the first bottom end effector dependent from a bottom distal link of the first bottom arm, each arm link of the first top arm being separate and distinct from each arm link of the first bottom arm, and the first top and bottom end effector extend overlapping each other at least in part; and extending, with a drive section having at least one motor connected to each respective arm of the pair of dual arms, each respective arm with at least one degree of freedom, independent of each other respective arm of the pair of dual arms, where the drive section has at least another motor connected to the base link so as to rotate the base link about the base pivot joint axis of rotation so that each corresponding end effector of the respective arm is extended and rotated along a substantially level substrate transport plane; wherein each respective top arm of the first and second dual arms, or each respective bottom arm of the first and second dual arms, are arranged to: effect substantially simultaneous dual extension and retraction with juxtaposed moves of the respective first top arm and second top arm, or the respective first bottom arm and second bottom arm, and effect extension and retraction of at least the first top arm or the second top arm along a radial path extending from the base pivot joint axis of rotation.

The method may include one or more of the following individually, in any combination with each other, and/or in any combination with the features described herein: the frame is a chamber arranged to hold a sealed atmosphere; the at least one motor is located within the sealed atmosphere of the chamber, housed in a sealed housing sealed from the sealed atmosphere, where the sealed housing seals the rotor or stator of the at least one motor from the sealed atmosphere; the at least one other motor of the drive section includes more than one other motor, each coupled to the base link and arranged so that the base link rotation about the base pivot joint axis of rotation has more than one degree of freedom; and the base link is configured so that the more than one degree of freedom are each disposed to effect rotation and extension, along the radial path, of the first top arm and the second top arm decoupled from rotation and extension, along the radial path, of the first bottom arm and second bottom arm.

It should be understood that the foregoing description is only illustrative of the present disclosure. Various alternatives and modifications can be devised by those skilled in the art without departing from the present disclosure. Accordingly, the present disclosure is intended to embrace all such alternatives, modifications and variances that fall within the scope of any claims appended hereto. Further, the mere fact that different features are recited in mutually different dependent or independent claims does not indicate that a combination of these features cannot be advantageously used, such a combination remaining within the scope of the present disclosure.

What is claimed is:

1. A substrate processing apparatus comprising:
a transport chamber having at least one lateral side, the at least one lateral side having at least two substrate transport ports arranged side by side;
a drive section connected to the transport chamber, the drive section having at least one motor defining at least one independent axis of rotation; and
a substrate transport apparatus mounted inside the transport chamber, the substrate transport apparatus including:
an upper arm link being operably coupled to the drive section and having a shoulder axis of rotation disposed at one end of the upper arm link, the upper arm link being pivotally mounted inside the transport chamber at the shoulder axis of rotation located within the transport chamber, and
at least one transfer arm, each transfer arm respectively having a corresponding substrate holder depending from the respective transfer arm separate and distinct from each other transfer arm, and each transfer arm being pivotally mounted to another end of the upper arm link at another axis of rotation, the other axis of rotation being a common axis of rotation, with respect to the upper arm link, that is common to the at least one transfer arm; and
wherein the upper arm link is linearly articulated, so that a translation portion of the upper arm link extends and retracts linearly between the shoulder axis of rotation and the other axis of rotation, and each transfer arm is coupled to the drive section so that each transfer arm respectively is coupled independently to and rotated independently by a different independent motor from the at least one motor of the drive section.

2. The substrate processing apparatus of claim 1, wherein the drive section includes a linear drive with another motor separate and distinct from each of the different independent motor, and each different independent motor respectively defines a corresponding independent axis of rotation of the at least one independent axis of rotation.

3. The substrate processing apparatus of claim 2, wherein the upper arm link includes a seal that seals the linear drive from an environment outside the upper arm link.

4. The substrate processing apparatus of claim 1, wherein the upper arm link includes a prismatic joint joining one or more of the at least one transfer arm to the upper arm link.

5. The substrate processing apparatus of claim 1, wherein the drive section has a distributed configuration with part of the drive section dependent from the upper arm link in a sealed housing with the different independent motor independently rotating the respective transfer arm, at the other axis of rotation, housed therein.

6. The substrate processing apparatus of claim 1, wherein each transfer arm is coupled independently to and rotated independently by the different independent motor for independent rotation of each transfer arm relative to another of the at least one transfer arm about the common axis of rotation, and effecting with each respective transfer arm independent transport of substrates on the corresponding substrate holder through each of the at least two substrate transport ports arranged side by side.

7. The substrate processing apparatus of claim 1, wherein the upper arm link is configured so as to extend and retract the other axis of rotation, relative to the shoulder axis, and position the other axis of rotation juxtaposed each substrate transport port of the at least two substrate transport ports in the at least one lateral side.

8. The substrate processing apparatus of claim 1, wherein the shoulder axis is located at a fixed location within the transport chamber, and a single side of the at least one lateral side has three substrate transport ports arranged side by side.

9. The substrate processing apparatus of claim 1, wherein the shoulder axis is mounted on a laterally traversing shuttle, and the transport chamber is an equipment front end module.

10. A method comprising:
providing a substrate processing apparatus including:
a transport chamber having at least one lateral side, the at least one lateral side having at least two substrate transport ports arranged side by side;
a drive section connected to the transport chamber, the drive section having at least one motor defining at least one independent axis of rotation; and
a substrate transport apparatus mounted inside the transport chamber, the substrate transport apparatus including:
an upper arm link being operably coupled to the drive section and having a shoulder axis of rotation disposed at one end of the upper arm link, the upper arm link being pivotally mounted inside the transport chamber at the shoulder axis of rotation located within the transport chamber, and
at least one transfer arm, each transfer arm respectively having a corresponding substrate holder depending from the respective transfer arm separate and distinct from each other transfer arm, and each transfer arm being pivotally mounted to another end of the upper arm link at another axis of rotation, the other axis of rotation being a common axis of rotation, with respect to the upper arm link, that is common to the at least one transfer arm;
where each transfer arm is coupled to the drive section so that each transfer arm respectively is coupled independently to and rotated independently by a different independent motor from the at least one motor of the drive section; and
linearly articulating the upper arm link so that a translation portion of the upper arm link extends and retracts linearly between the shoulder axis of rotation and the other axis of rotation.

11. The method of claim 9, wherein the drive section includes a linear drive with another motor separate and distinct from each of the different independent motor, and each different independent motor respectively defines a corresponding independent axis of rotation of the at least one independent axis of rotation.

12. The method of claim 10, wherein the upper arm link includes a seal that seals the linear drive from an environment outside the upper arm link.

13. The method of claim 10, wherein the upper arm link includes a prismatic joint joining one or more of the at least one transfer arm to the upper arm link.

14. The method of claim 9, wherein the drive section has a distributed configuration with part of the drive section dependent from the upper arm link in a sealed housing with the different independent motor independently rotating the respective transfer arm, at the other axis of rotation, housed therein.

15. The method of claim 9, wherein each transfer arm is coupled independently to and rotated independently by the different independent motor for independent rotation of each transfer arm relative to another of the at least one transfer arm about the common axis of rotation, and effecting with each respective transfer arm independent transport of substrates on the corresponding substrate holder through each of the at least two substrate transport ports arranged side by side.

16. The method of claim 9, wherein the upper arm is extends and retracts the other axis of rotation, relative to the shoulder axis, and positions the other axis of rotation juxtaposed each substrate transport port of the at least two substrate transport port in the at least one lateral side.

17. The method of claim 9, wherein the shoulder axis is located at a fixed location within the transport chamber, and a single side of the at least one lateral side has three substrate transport ports arranged side by side.

18. The method of claim 9, wherein the shoulder axis is mounted on a laterally traversing shuttle, and the transport chamber is an equipment front end module.

19. A substrate transport apparatus comprising:
a frame;
a base link pivotally joined to the frame so as to rotate relative to the frame about a base pivot joint axis of rotation fixed to the frame;
a pair of dual arms having first dual arms and second dual arms, the first dual arms are juxtaposed with respect to the second dual arms, the first dual arms have a first top arm with a first top end effector, and a first bottom arm with a first bottom end effector, and the second dual arms have a second top arm with a second top end effector, and a second bottom arm with a second bottom end effector;
the first top arm has a corresponding top terminal joint, and the first bottom arm has a corresponding bottom terminal joint, each of the first top arm and the first bottom arm respectively rotates and extends from the corresponding top terminal joint and bottom terminal joint, the top terminal and bottom terminal joint being coaxial and respectively joining each first top and bottom arm to the base link via the corresponding top terminal joint and bottom terminal joint, the first top arm has at least one first top arm link and the first top end effector dependent from a top distal link of the first top arm, and the first bottom arm has at least one bottom arm link and the first bottom end effector dependent from a bottom distal link of the first bottom arm, each arm link of the first top arm being separate and distinct from each arm link of the first bottom arm, and the first top and bottom end effector extend overlapping each other at least in part; and
a drive section with at least one motor connected to each respective arm, of the pair of dual arms, arranged to extend each respective arm with at least one degree of freedom, independent of each other respective arm of the pair of dual arms, and the drive section has at least another motor connected to the base link so as to rotate the base link about the base pivot joint axis of rotation so that each corresponding end effector of the respective arm is extended and rotated along a substantially level substrate transport plane;
wherein each respective top arm of the first and second dual arms, or each respective bottom arm of the first and second dual arms, are arranged to:
effect substantially simultaneous dual extension and retraction with juxtaposed moves of the respective first top arm and second top arm, or the respective first bottom arm and second bottom arm, and
effect extension and retraction of at least the first top arm or the second top arm along a radial path extending from the base pivot joint axis of rotation.

20. The substrate transport apparatus of claim 19, wherein the frame is a chamber arranged to hold a sealed atmosphere.
